(19) United States
(12) Patent Application Publication
(10) Pub. No.: US 2022/0239236 A1
(43) Pub. Date: Jul. 28, 2022

(54) TRIBOELECTRIC ENERGY GENERATION METHODS AND ARTICLES

(71) Applicant: Liquid X Printed Metals, Inc., Pittsburgh, PA (US)

(72) Inventor: Robert G. SWISHER, Pittsburgh, PA (US)

(21) Appl. No.: 17/612,732

(22) PCT Filed: May 20, 2020
(86) PCT No.: PCT/US2020/033733

§ 371 Date: Nov. 19, 2021

Related U.S. Application Data
(60) Provisional application No. 62/850,162, filed on May 20, 2019.

(51) Int. Cl. H02N 1/04; C09D 11/52; H05K 1/03; H05K 3/12; H05K 1/09

(52) U.S. Cl. CPC H02N 1/04; C09D 11/52; H05K 1/038; H05K 2203/0783; H05K 3/1283; H05K 1/095; H05K 3/125

(57) ABSTRACT

Described herein are triboelectric energy generators that generally include a first flexible layer having a first electron donating material coated on at least a first surface and an electron accepting material coated over the first electron donating material, and a second flexible layer having a second electron donating material coated on at least a first surface. The first and second layers are positioned adjacent each other with their first surfaces facing inward toward each other and separated by a gap distance. An electric potential is generated upon movement between the first and second flexible layers, such as at least alternating contact and no-contact between the first and second flexible layers. The electron donating material may be provided by a particle-free conductive ink.

### CROSS-REFERENCE TO RELATED APPLICATIONS

The present application claims the benefit under 35 U.S.C. § 119(e) of prior U.S. Provisional Application Ser. No. 62/850,162, filed May 20, 2019, the entire content of which is incorporated herein.

### TECHNICAL FIELD

This invention pertains generally to methods for energy generation in flexible substrates using the triboelectric effect, and more specifically to flexible triboelectric energy nanogenerators, methods of producing the flexible triboelectric energy nanogenerators, and textiles comprising such energy nanogenerators.

### BACKGROUND

The triboelectric effect is the electrification of a substrate upon frictional contact with another substrate having a different work function. Work function, expressed in units of eV, refers to the amount of energy required to remove an electron from the surface of any given solid. Those materials that collect more negative charge have larger work functions. For example, silicone rubber has a much larger work function (about 14 eV) than aluminum (about 5 eV). Thus, when materials having different work functions are brought into frictional contact, such as silicone rubber and aluminum, opposite charges may develop on the materials.

Based on this triboelectric effect, Wang and coworkers fabricated a triboelectric nanogenerator (TENG) in 2012 that effectively converts various mechanical energies into electricity. (Flexible triboelectric generator, 2012, Nano Energy, vol. 1, pgs. 328-334). With the fast-growing demand for flexible electronics, such as wearable electronics, development of flexible TENGs as power sources for these flexible electronics offered several major environmental and material advantages. Maximizing the charge generated on each of the differing materials is critical, however, to providing enough charge to power the electronic devices. Moreover, providing TENGs that are stable on these flexible substrates is also critical to their use in e-textiles and on other flexible electronics.

Thus, an object of the present invention is to provide flexible triboelectric energy nanogenerators that may produce enough charge to power electronic devices and may be stably integrated on a flexible substrate such as a textile. Additionally, an object of the present invention is to provide scalable methods for producing these triboelectric energy nanogenerators so they may be integrated into, and provide power to, a wider range of end products.

### SUMMARY

Described herein are triboelectric energy nanogenerators that may be stably incorporated into flexible substrates, such as textiles. These generators include at least two flexible material layers that are configured to provide a work function differential therebetween and may thus provide power to charge/power an electronic device.

Accordingly, the present invention relates to a triboelectric energy generator comprising: a first flexible layer having a first electron donating material coated on at least a first surface and an electron accepting material coated over the first electron donating material; and a second flexible layer having a second electron donating material coated on at least a first surface, wherein the first and second layers are positioned adjacent each other with their first surfaces facing inward toward each other and separated by a gap distance, and wherein an electric potential is generated upon movement between the first and second flexible layers. The movement is at least alternating contact and no-contact between the first and second flexible layers.

The present invention also relates to a triboelectric energy generator comprising: a first flexible layer having a first electron accepting material coated on at least a first surface; a second flexible layer having a second electron accepting material coated on at least a first surface; and a third flexible layer comprising an electron donating material, wherein the first and second layers are positioned adjacent each other with their first surfaces facing inward toward each other with the third flexible layer positioned therebetween, wherein each of the flexible layers are separated by a gap distance, and wherein an electric potential is generated upon movement between the first, second, and third flexible layers.

According to certain aspects, the first, second, and/or third flexible layers may be textile layers. Exemplary textile materials include at least a knit, woven, or nonwoven fabric comprising fibers of polyester, polyamides, spandex, nylon, Evolon®, elastane, cotton, cellulose, silk, wood, wool, or blends thereof.

According to certain aspects, the electron donating material may comprise a conductive metal film deposited by a particle-free metal ink. Exemplary metals of the metal ink include copper, silver, gold, or nickel.

According to certain aspects, the first, second, and/or third flexible layers are textile layers, and the conductive metal film conformally coats fibers of the textile.

According to certain aspects, the gap distance may be about 0.01 mm to about 5 mm, such as 0.1 mm to about 2 mm.

According to certain aspects, a work function of the electron accepting material may be at least 3 eV greater than a work function of the electron donating material, such as at least 5 eV greater, or even 8 eV greater.

According to certain aspects, the electron accepting material may be a flexible polymeric material, such as a polyimide. The electron accepting material may be an elastomeric material such as polydimethylsiloxane or silicon rubber.

According to certain aspects, the triboelectric energy generator may further comprise additional flexible layer(s) positioned within the gap(s) between the flexible layers. For example, the additional flexible layer may comprise a mesh material, such as a mesh material having at least a 60% open area, such as at least an 80% open area. Exemplary materials of the mesh may include a flexible polymeric material, such as nylon.

According to certain aspects, the triboelectric energy generator may further comprise a protective coating, such as an abrasion resistant coating, over the electron donating materials.

According to certain aspects, the flexible layer comprising the electron donating material may include a raised pattern, wherein the raised pattern may be formed by thermoforming or embossing the second flexible layer. A depth of the raised pattern may define the gap distance. For example, when the triboelectric energy generator comprises three flexible layers, the third layer positioned between the first and second flexible layers may comprise the raised pattern. Alternatively, when the triboelectric energy generator comprises two flexible layers, the second layer comprising the electron donating material includes the raised pattern.

The present invention also relates to a method for forming a triboelectric energy generator in a flexible substrate. The method generally comprises: depositing a first particle-free conductive ink on at least a first side of a first flexible substrate; coating the particle-free conductive ink on the first side of the first flexible substrate with an electron accepting material; and depositing a second particle-free conductive ink on at least a first side of a second flexible substrate, wherein the first and second flexible substrates are positioned adjacent each other with their first surfaces facing inward toward each other and separated by a gap distance, and wherein an electric potential is generated upon movement between the first and second flexible layers.

According to certain aspects, the first and second particle-free conductive ink may be the same or different.

According to certain aspects, the method further comprises: depositing a particle-free conductive ink on at least a first side of a third flexible substrate; coating the particle-free conductive ink on the first side of the third flexible substrate with an electron accepting material; and positioning the third flexible layer adjacent the second flexible layer with the first side facing inward toward the second flexible layer. The particle-free ink on the third flexible layer may be the same or different from the first and second particle-free inks on the first and second layers.

According to certain aspects, the method may further comprise thermoforming or embossing the flexible layer comprising the electron donating material to form a raised pattern having a depth substantially equal to the gap distance, i.e., the second flexible layer.

According to certain aspects, the method may further comprise, after depositing a particle-free conductive ink, reducing the ink to provide a metallic conductive film. The reducing step may comprise one or more of: exposing the substrate to an elevated temperature; exposing the substrate to a reactive gas; and exposing the substrate to irradiation. The method may further yet comprise, after reducing the ink to provide the metallic conductive film, coating at least the metallic conductive film with a protective coating.

According to certain aspects, the particle-free metal ink comprises a metal complex dissolved in one or more polar protic solvents, wherein the metal complex comprises a metal, a first ligand that is a sigma donor to the metal and volatilizes upon heating the metal complex, and a second ligand, which is different from the first ligand and also volatilizes upon heating the metal complex. Exemplary metals include copper, silver, gold, or nickel.

According to certain aspects, the first ligand of the metal complex may be an amine or a thioether, and the second ligand of the metal complex may be a carboxylate. According to certain aspects, the one or more polar protic solvents may comprise one or more of water, an alcohol, an amine, an amino alcohol, and a polyol. According to certain aspects, the particle-free conductive ink may comprise from 0.1% to 5% of an additive selected from one or more of a binder, a surfactant, a dispersant, and a dye. According to certain aspects, the particle-free conductive ink may have a viscosity measured at 25° C. of 25 cps or less, such as 20 cps or less.

According to certain aspects, the flexible substrate(s) may be textiles substrates, such as a knit, woven, or nonwoven fabric comprising fibers of polyester, polyamides, spandex, nylon, Evolon®, elastane, cotton, cellulose, silk, wood, wool, or blends thereof. According to certain aspects, the textile substrate may be pretreated with oxygen plasma, corona, a protective coating, or a combination thereof.

### BRIEF DESCRIPTION OF THE DRAWINGS

Aspects, features, benefits and advantages of the embodiments herein will be apparent with regard to the following description, appended claims, and accompanying drawings. In the following figures, like numerals represent like features in the various views. It is to be noted that features and components in these drawings, illustrating the views of embodiments of the presently disclosed invention, unless stated to be otherwise, are not necessarily drawn to scale.

FIG. 1 illustrates a schematic diagram of the triboelectric effect;

FIGS. 2-7 illustrate various triboelectric energy generators according to various aspects of the presently disclosed invention;

FIG. 8 shows a scanning electron micrograph (SEM) of a woven textile having a conductive ink conformally coated on a portion thereof (800× magnification) according to certain aspects of the presently disclosed invention;

FIG. 9 shows a proton nuclear magnetic resonance (¹H-NMR) scan of an exemplary metal complex (ethylenediamine-silver(I) isobutyrate in D₂O) according to certain aspects of the presently disclosed invention, and (upper right) the structure of an exemplary conductive ink of the present invention;

FIG. 10 shows a graph of the resistance (ohms) after multiple wash cycles for a conductive trace on a textile using inks and methods in accordance with certain aspects of the presently disclosed invention;

FIG. 11 shows a graph of the change in resistance with increased strain (stretch) for a conductive trace on a textile using inks and methods in accordance with certain aspects of the presently disclosed invention;

FIG. 12 shows a graph of the change in resistance with increased bending cycles for a conductive trace on a textile using inks and methods in accordance with certain aspects of the presently disclosed invention;

FIGS. 13A-13B show oscilloscope traces for triboelectric energy generators in accordance with certain aspects of the presently disclosed invention;

FIG. 14 shows an exemplary system comprising a triboelectric energy generator according to certain aspects of the presently disclosed invention; and

FIG. 15 shows an exemplary oscilloscope trace for the system of FIG. 14.

### DETAILED DESCRIPTION

In the following description, the present invention is set forth in the context of various alternative embodiments and implementations involving methods of generating energy using the triboelectric effect, and textile articles configured to generate energy by the triboelectric effect. The methods and articles use particle-free conductive inks and novel methods for printing those inks. While the following description discloses numerous exemplary embodiments, the scope of the present patent application is not limited to the disclosed embodiments, but also encompasses combinations of the disclosed embodiments, as well as modifications to the disclosed embodiments.

Various aspects of the triboelectric energy nanogenerators (TENGs), particle-free conductive inks used to produce these generators, and flexible substrates comprising these generators as disclosed herein may be illustrated by describing components that are coupled, attached, and/or joined together. As used herein, the terms “coupled”, “attached”, and/or “joined” are interchangeably used to indicate either a direct connection between two components or, where appropriate, an indirect connection to one another through intervening or intermediate components. In contrast, when a component is referred to as being “directly coupled”, “directly attached”, and/or “directly joined” to another component, there are no intervening elements shown in said examples.

Various aspects of the TENGs, inks, substrates, and methods disclosed herein may be described and illustrated with reference to one or more exemplary implementations. As used herein, the term “exemplary” means “serving as an example, instance, or illustration,” and should not necessarily be construed as preferred or advantageous over other variations of the devices, systems, or methods disclosed herein. “Optional” or “optionally” means that the subsequently described event or circumstance may or may not occur, and that the description includes instances where the event occurs and instances where it does not. In addition, the word “comprising” as used herein means “including, but not limited to”.

Relative terms such as “lower” or “bottom” and “upper” or “top” may be used herein to describe one element's relationship to another element illustrated in the drawings. It will be understood that relative terms are intended to encompass different orientations of aspects of the TENGs disclosed herein in addition to the orientation depicted in the drawings. By way of example, if aspects of the TENG in the drawings are turned over, elements described as being on the “bottom” side of the other elements would then be oriented on the “top” side of the other elements as shown in the relevant drawing. The term “bottom” can therefore encompass both an orientation of “bottom” and “top” depending on the particular orientation of the drawing.

It must also be noted that as used herein and in the appended claims, the singular forms “a”, “an”, and “the” include the plural reference unless the context clearly dictates otherwise. For example, although reference is made to “a” flexible layer, “an” ink, “a” metal complex, and “the” TENG, one or more of any of these components and/or any other components described herein can be used.

Moreover, other than in any operating examples, or where otherwise indicated, all numbers expressing, for example, quantities of ingredients used in the specification and claims are to be understood as being modified in all instances by the term “about”. Accordingly, unless indicated to the contrary, the numerical parameters set forth in the following specification and appended claims are approximations that may vary depending upon the desired properties to be obtained by the present invention. At the very least, and not as an attempt to limit the application of the doctrine of equivalents to the scope of the claims, each numerical parameter should at least be construed in light of the number of reported significant digits and by applying ordinary rounding techniques.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard variation found in their respective testing measurements.

“Substantially free”, as used herein, is understood to mean inclusive of only trace amounts of a constituent. “Trace amounts” are those quantitative levels of a constituent that are barely detectable and provide no benefit to the functional properties of the subject composition, process, or articles formed therefrom. For example, a trace amount may constitute 1.0 wt. %, 0.5 wt. %, 0.1 wt. %, 0.05 wt. %, or even 0.01 wt. % of a component of any of the particle-free ink formulations disclosed herein. “Totally free”, as used herein, is understood to mean completely free of a constituent.

Unless defined otherwise, all technical and scientific terms used herein have the same meanings as commonly understood by one of ordinary skill in the art.

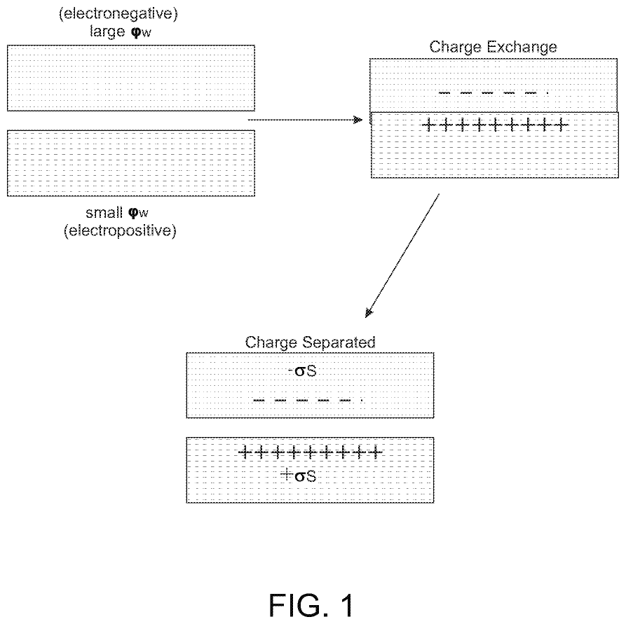

The present invention provides methods for methods of generating energy using the triboelectric effect, and textile articles configured to generate energy by the triboelectric effect. The triboelectric effect is implemented in the present invention using materials having different work functions φ_{w} such that electrons are exchanged when the materials are brought into contact, i.e., generate surface charges. Rubbing of the materials together is not essential as long as intimate contact is made. When the two materials separate, an electrostatic voltage is produced, which establishes a force to move the charges back if there is a conducting path. When at least one of the materials is not conductive at the surface, surface charges remain after the separation, and may move toward a storage area or device (see FIG. 1).

At least one of the materials of the presently disclosed invention includes a conductive material having a small work function, such as a metal. A second material may then include any material having a larger work function than the first material. In order that the charge remain at the gap between the materials after contact is made therebetween, a non-conductive second material may be preferable. For example, a plastic or elastomeric material having a larger work function that is non-conductive may be selected for the second material.

In order that the first conductive material may be provided on a flexible substrate, such as a textile, the inventive processes disclosed herein use conductive particle-free inks. These inks may be directly printed on the textile, and thus provide highly scalable and automated methods for producing the metal layer of material used in the novel TENGs disclosed herein. Moreover, the conductive inks disclosed herein provide conformal coating of the textile fibers that allows for greatly improved conductivity and longevity of the conductive trace or film. As used herein, the term “conformal” shall be taken to mean a coating that covers at least the surface of a textile, fiber, or substrate, and which follows the contours of the surface.

Triboelectric Energy Generators

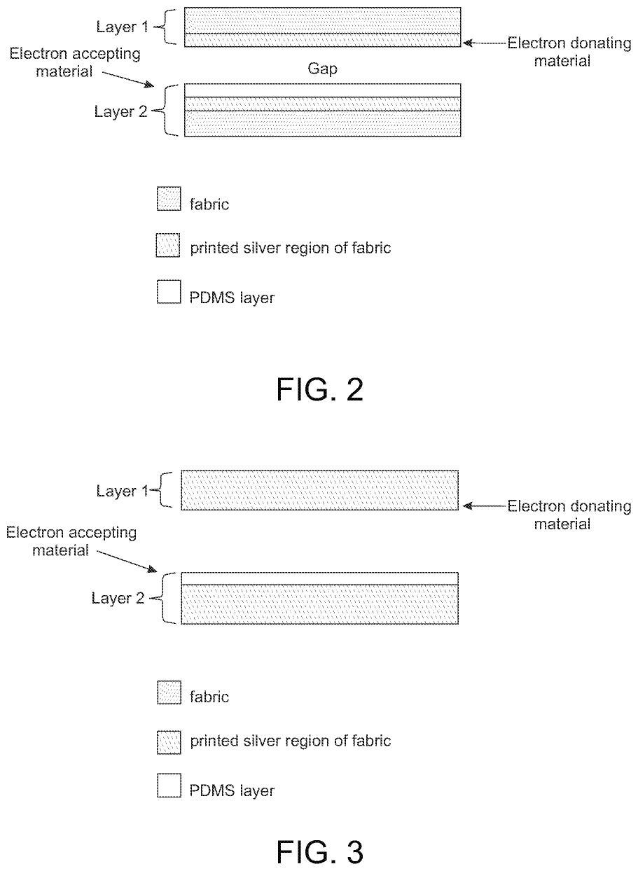

The triboelectric energy generators (TENGs) of the present invention are provided on flexible substrates. As shown in FIG. 2, a TENG according to the presently disclosed invention may include a first flexible substrate layer (“layer 1”) having an electron donating material coated on a first surface and a second flexible layer (“layer 2”) having an electron donating material coated on a first surface. As shown in FIG. 2, the first flexible layer and the second flexible layer are adjacent each other with their respective first surfaces facing inward toward each other (i.e. the electron donating materials face each other).

According to certain aspects, the electron donating material may be a conductive film deposited by a particle-free conductive ink (see section below). The inks may include at least one metal complex, wherein exemplary metals comprise at least copper, silver, nickel, gold, and alloys of these metals. The particle-free conductive ink may be deposited by any method known in the art, such as direct printing as detailed herein, dip coating, polling, brushing, spraying, etc. Exemplary methods include at least direct printing and dip coating.

The metal complex in the particle-free conductive inks may be reduced to form the conductive metal trace or film by exposure to an elevated temperature, exposure to a reactive gas, exposure to irradiation, or any combination thereof.

The conductive metal film may be stabilized, i.e., protected from abrasion, by application of a protective coating thereon. Such methods and exemplary coatings are listed hereinbelow. According to certain aspects, only one of the conductive metal films may be coated, such as the metal film on the second flexible layer. That is, when the metal film on the first flexible layer includes an additional coating, such as the electron accepting material discussed below, it may not include the protective coating.

According to certain aspects, the first flexible layer of the TENG may include an electron accepting material coated over the electron donating material (see FIG. 2). Exemplary electron accepting materials will be flexible and will have a work function that is larger than the work function of the electron donating material. For example, the work function of the electron accepting material may be at least 3 eV greater than the work function of the electron donating material, such as at least 5 eV greater, or 7 eV greater, or even about 9 eV greater.

The electron accepting material may be a flexible polymeric material, such as polyimide (e.g., KAPTON®). The electron accepting material may be an elastomeric material, such as polydimethylsiloxane (PDMS) or silicone rubber.

As shown in FIG. 2, the TENG will include a space (“gap”) between the first flexible layer and the second flexible layer. This space may be reduced so that the first and second flexible layers come into intimate contact by a movement, and the space may be restored by a reversal of this movement. For example, the movement may be a vertical (based on the orientation of the TENG shown in FIG. 2) movement that forces the two layers together, such as by bending, folding, external pressure, etc. It is the repeated nature of the movement (contact to no-contact to contact, etc.) that generates an electrical charge at the material surfaces. This change may then be transported on at least one of the conductive surfaces for storage, such as in a capacitor or other battery.

As shown in FIG. 2, the first and second electron donating materials may be coated on a surface of the first and second flexible substrates, respectively. With reference to FIG. 3, according to certain aspects of the present invention, the first and second electron donating materials may coat an entire thickness of the first and second flexible material.

A wide variety of flexible materials may be used to form the presently disclosed TENGs. For example, any of polymers, plastics, organic and synthetic fibers may be used. In particular examples, the substrate is a textile such as a knit, woven, or nonwoven fabric formed of organic or synthetic fibers. Exemplary fibers of such textile substrates include at least polyester, polyamides, spandex, polyester-spandex, nylon, nylon-spandex, Evolon®, elastane, and other synthetic materials, in addition to organic materials (e.g., cotton, cellulose, silk, wood, wool fibers, leather, suede). Blends of any of these materials are also possible.

According to certain aspects of the invention, the textiles may be pretreated with a reactive gas, such as an O₂ plasma or corona, that may improve deposition of the particle-free conductive inks thereon and may reduce sheet resistance.

Additionally, the textiles may be prewashed and dried prior to deposition or printing of the conductive inks disclosed herein.

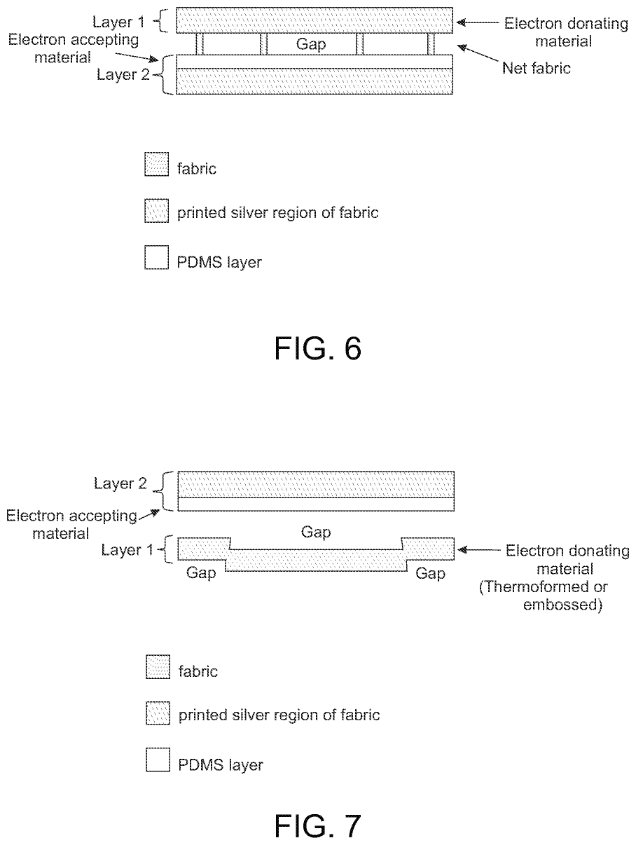

The gap formed between the first and second flexible layers (layer 1 and layer 2 of FIGS. 2 and 3) may be maintained by inclusion of a third layer, such as a mesh layer (see FIG. 6, “net fabric”). The mesh layer may have a thickness that defines a width of the gap (i.e. distance between the first and second flexible layers). The mesh may be formed of a flexible polymeric material, such as nylon or another insulating material. The mesh may provide a percent open space (% open portion versus closed portion of the mesh on a surface thereof, i.e. 2 dimensions) of at least 60%, such as 65%, or 70%, or 75%, or 80%, or 85%, or 90%.

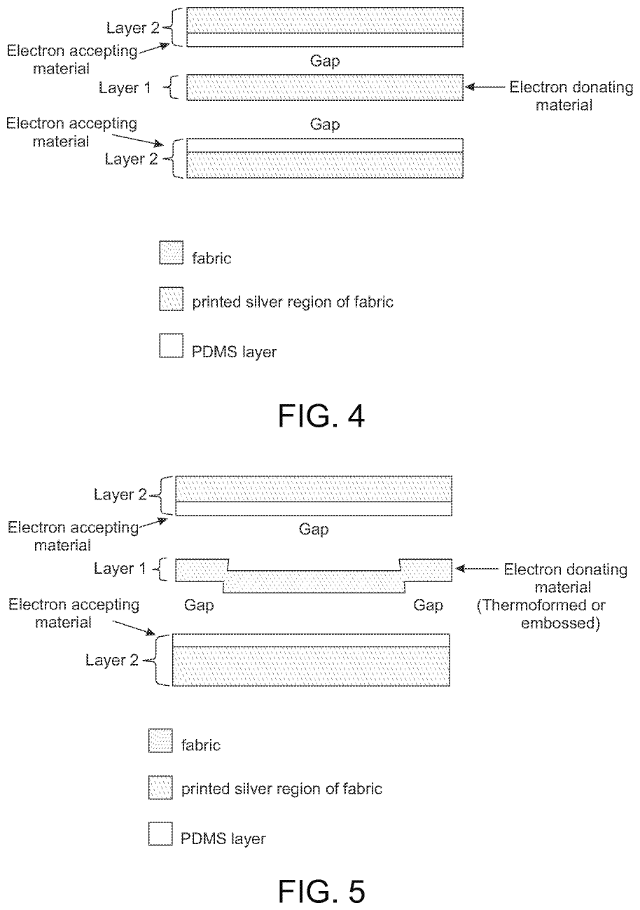

As shown in FIG. 4, a TENG of the presently disclosed invention may include two electron accepting material layers (“layer 2”), and one electron donating material layer (“layer 1”). For example, first and second flexible substrates may each be coated on a first surface thereof with an electron accepting material, such as an elastomeric material as described hereinabove. These substrate layers may be position adjacent each other so that the surfaces having the electron accepting material may be positioned facing each other (see FIG. 4). Positioned between the first and second flexible substrates may be a third flexible substrate having the electron donating material coated thereon (“layer 1”). As shown, the electron donating material may be coated on both sides of the third flexible substrate or may saturate the third flexible substrate. A gap may be formed between the first and third flexible substrates, and between the third and second flexible substrates. These gaps may be maintained by additional layers, such as by one or more mesh layers, as discussed above.

Alternatively, the gap(s) may be maintained by a raised pattern formed on the third flexible substrate layer. As shown in FIG. 5, the third flexible substrate layer may include raised areas, such as a pattern formed by embossing or thermoforming of the third flexible layer. Alternatively, the electron donating material shown as layer 1 in FIG. 2 or 3 could be formed to include a raised pattern (embossed or thermoformed), as shown in FIG. 7.

While various arrangements of flexible layers are shown in the figures, the present invention envisions other arrangements, such as additional layers (i.e., stacks of TENGs as shown in the figures), or arrangements of the layers, as long as at least one electron donating material and at least one electron accepting material are provided with a gap therebetween so that repetitive contact—no-contact may be used to generate an electric charge and thus form a charge current.

Moreover, while specific electron donating and electron accepting materials are shown in FIGS. 2-7, such is for illustrative purposes only, and various other materials as disclosed herein, and combinations thereof are within the scope of the present invention.

In exemplary embodiments, the one or more electron donating materials may be deposited on the flexible substrates using any of the particle-free conductive inks disclosed herein. The one or more electron accepting layers may be, or may be coated by, any flexible material having a work function that is larger than the work function of the electron donating material. For example, the work function of the electron accepting material may be at least 3 eV greater than the work function of the electron donating material, such as at least 5 eV greater, or 7 eV greater, or even about 9 eV. The electron accepting material may be a flexible polymeric material. Exemplary flexible polymeric materials include at least polyimide, and elastomeric materials, such as polydimethylsiloxane (PDMS) and/or silicone rubber.

Particle-Free Conductive Inks

The particle-free conductive inks of the present invention generally include a metal complex dissolved in a solvent. The metal complex can be mononuclear, dinuclear, trinuclear, and higher. For example, the metal complex may be a neutral metal complex comprising at least one metal (M), at least one first ligand (L₁), and at least one second ligand (L₂). The metal complex may be as described in US Patent Application Publications 2011/0111138 and 2013/0236656. The metal complex may comprise a first metal complex having at least one first metal, and a second metal complex having at least one second metal. The metal complex may be as described in U.S. Pat. No. 9,920,212.

For example, according to certain aspects of the present invention, a neutral metal complex may be formed by first forming a complex between the metal (M) and the second ligand (L₂), such as by reacting a metal, metal salt, or metal oxide with the second ligand. The metal-second ligand complex may then be reacted with an excess of the first ligand (L₁) to form the neutral metal complex. The stoichiometric reaction ratio between the first ligand and the metal-second ligand complex can be, for example, at least 2:1, such as at least 5:1, or at least 10:1, or at least 13:1, or at least 15:1, or at least 20:1. When formulated in this way, the reaction mixture remains substantially or totally free of particles, and progresses to completion forming a metal complex having stoichiometric amounts of the first and second ligands and the metal.

The excess, unreacted first ligand (L₁) may be removed to provide the metal complex having stoichiometric amounts of the metal, first ligand, and second ligand (i.e., free of unliganded first ligand). According to certain aspects of the invention, the excess, unreacted first ligand may be removed by vacuum evaporation of the complex and may include one or more wash steps with an appropriate solvent, to yield a final dry powder having stoichiometric amounts of the metal, first ligand, and second ligand. For silver metal complexes, this powder is typically white.

The resulting purified metal complexes are substantially or totally free of particles (particle-free) including nanoparticles and microparticles and are highly soluble in various solvents. This differs greatly from prior art complexes which do not include stoichiometric amounts of the metal, first ligand, and second ligand; and/or may include residual unliganded first ligand; and generally, include particles such as nanoparticles and/or microparticles. Printing of these prior art nanoparticle inks on certain textiles has demonstrated that they often do not penetrate into the textile, but rather pool on top of the textile. The conductive inks of the present invention are capable of conformally coating fibers of a textile substrate.

According to certain aspects of the present invention, the conductive inks may be formulated by dissolving at least one purified metal complex, which is free of any unreacted first ligand, in an organic solvent system such as a hydrocarbon solvent system.

According to certain aspects of the present invention, the conductive inks may be formulated by dissolving at least one purified metal complex, which is free of any unreacted first ligand, in at least one polar protic solvent, such as at least two polar protic solvents. In general, polar protic solvents can have high polarity and high dielectric constants. Polar protic solvents may comprise, for example, at least one hydrogen atom bound to an oxygen or a nitrogen. Polar protic solvents may comprise, for example, at least one acidic hydrogen. Polar protic solvents may comprise, for example, at least one unshared electron pair. Polar protic solvents may display, for example, hydrogen bonding.

The viscosity of hydrogen bonding solvents is inherently greater than non-hydrogen bonding solvents such as hydrocarbons. Further the elevated solvent boiling points (due to energetically greater intermolecular forces) and polar ink nature render them capable and competent systems for the formation of thin films and structures of greater quality than strictly hydrocarbon or aromatic hydrocarbon delivery systems due to slower controlled drying times, surface tensions, and surface wetting properties.

Polar protic solvents may be particularly useful for depositing the conductive inks on certain substrates, since hydrocarbon solvent(s) may not be compatible with the substrate and/or may not be recommended in some situations. Moreover, polar protic solvents may provide a more environmentally friendly ink solution.

Examples of polar protic solvents include water, linear or branched alcohols, amines, amino alcohols, and hydroxyl-terminated polyols including glycols. The polar protic solvent may also be, for example, ethylene and higher glycols, as well as alcohols. Particular examples of polar protic solvents include water, methanol, ethanol, n-propanol, isopropanol, n-butanol, acetic acid, formic acid, and ammonia.

The polar protic solvent may include, for example, at least one amine solvent. The amine solvent may have a molecular weight of, for example, about 200 g/mol or less, or about 100 g/mol or less. The amine solvent may be, for example, at least one monodentate amine, at least one bidentate amine, and/or at least one polydentate amine. The amine solvent may be, for example, at least one primary amine or at least one secondary amine. In one embodiment, the amine solvent may comprise at least one alkyl group bonded to at least one primary or secondary amine. In one particular embodiment, the amine solvent may comprise at least two primary or secondary amine groups connected by a linear or branched alkyl group. In another particular embodiment, the amine solvent may comprise at least two linear or branched alkyl groups connected by at least one secondary amine. Advantages of the amine solvent include, for example, improved solubility and thus higher possible concentrations of the metal complex in the solvent, as well as lower decomposition temperatures for the metal complex.

The conductive inks of the present invention may be formulated to include hydrogels and/or polymers, such as polyacrylic acids, having lower molecular weights, and which may function as viscosity modifiers. For example, the compositions may include up to 5 wt. % of a hydrogel and/or polymer, such as up to 4 wt. %, or up to 3 wt. %, or up to 2 wt. %, or up to 1 wt. %, or up to 0.5 wt. %, or up to 0.1 wt. %, or up to 0.05 wt. %. The compositions may include hydrogels and/or polymers at from 0.01 wt. % to 5 wt. %, such as 0.01 wt. % to 4 wt. %, or 0.01 wt. % to 3 wt. %, or 0.01 wt. % to 2 wt. %, or 0.01 wt. % to 1 wt. %. According to certain aspects, the polymer may be a conductive polymer, such as any of the polyacetylenes, polyanilines, polyphenylenes, polypyrenes, polypyrroles, polythiophenes, etc. known in the art.

The metal complexes described herein may have a solubility in at least one polar protic solvent at 25° C. of at least 50 mg/ml, or at least 100 mg/ml, or at least 150 mg/ml, or at least 200 mg/ml, or at least 250 mg/ml, or at least 300 mg/ml, or at least 400 mg/ml, or at least 500 mg/ml, or at least 1,000 mg/ml, or at least 1,500 mg/ml, or even or at least 2,000 mg/ml.

According to certain aspects, the amount of organic solvent in the conductive inks disclosed herein can be, for example, less than 30 wt. %, less than 20 wt. %, less than 10 wt. %, less than 5 wt. %, less than 3 wt. %, less than 1 wt. %, less than 0.1 wt. % or less than 0.01 wt. %. According to certain aspects, the conductive ink formulations may be substantially or totally free of organic solvent.

Analysis of the conductive ink formulations, in either of the organic or polar protic solvent systems, has shown that the amounts of the metal, and first and second ligands, in the ink solutions are stoichiometric (see Examples).

According to certain aspects of the present invention, the viscosity of the ink formulations measured at 25° C. can be, for example, about 800 cps or less, about 500 cps or less, about 250 cps or less, or about 100 cps or less. According to certain other aspects, the viscosity of the ink formulations measured at 25° C. can be, for example, about 50 cps or less, 40 cps or less, 30 cps or less, 25 cps or less, 20 cps or less, or even 10 cps or less. According to yet other aspects, the ink formulations have a viscosity of about 1 cps to about 20 cps, or about 1 cps to about 15 cps, or about 1 cps to about 10 cps.

According to certain aspects of the present invention, the viscosity of the ink formulations measured at 25° C. can be, for example, about 800 cps or more, such as about 1500 cps or more, about 2,500 cps or more, about 5,000 cps or more, or even about 10,000 cps or more.

The conductive ink formulations may be substantially or totally free of particles, microparticles, and nanoparticles. In particular, the conductive ink formulations comprising the metal complex may be substantially or totally free of nanoparticles including metal nanoparticles, or free of colloidal material. For example, the level of nanoparticles can be less than 1 wt. %, less than 0.1 wt. %, or less than 0.01 wt. %, or less than 0.001 wt. %. One can examine the composition for particles using methods known in the art including, for example, SEM and TEM, spectroscopy including UV-Vis, dynamic light scattering, plasmon resonance, and the like. Nanoparticles can have diameters of, for example, 1 nm to 500 nm, or 1 nm to 100 nm. Microparticles can have diameters of, for example, 0.5 μm to 500 μm, or 1 μm to 100 μm.

Metal Complex

The metal complex may comprise a metal useful for forming electrically conducting lines, particularly those metals used in the semiconductor and electronics industries. Exemplary metals include at least silver, gold, copper, platinum, ruthenium, nickel, cobalt, palladium, zinc, iron, tin, indium, and alloys thereof. The metal complexes may comprise a single metal center or two metal centers.

For example, the metal complex may be a neutral metal complex comprising at least one metal, at least one first ligand, and at least one second ligand. The first ligand may be adapted to volatilize when heated without formation of a solid product. For example, the first ligand may volatize upon heating at a temperature of, for example, 250° C. or less, or 200° C. or less, or 150° C. or less. Heating can be done in the presence or absence of oxygen. The first ligand may be a reductant for the metal. The first ligand may be in neutral state, such as neither an anion nor a cation.

The first ligand may be a monodentate ligand, or a polydentate ligand including, for example, a bidentate or a tridentate ligand. According to certain aspects of the invention, the first ligand may be a thioether, such as tetrahydrothiophene, a phosphine, or an amine compound. In certain examples, the first ligand may comprise an amine compound having at least two primary amine groups. Primary amines are stronger reducing agent than alcohols and are capable of forming homogenous solutions with polar protic solvents. Moreover, the first ligand may comprise two primary amine end groups and no secondary amine group, or one primary amine end group and one secondary amine end group. In this latter example, the secondary amine end group may be substituted with a linear alkane or a polar group, such as a hydroxy or alkoxy. In yet another example, the first ligand may comprise two primary amine end groups and one secondary amine group. The first ligand may be an amine including an alkyl amine. The alkyl groups can be linear, branched, or cyclic. Bridging alkylene can be used to link multiple nitrogen together. In the amine, the number of carbon atoms can be, for example, 15 or less, or 10 or less, or 5 or less.

The molecular weight of the first ligand, may be, for example, about 1,000 g/mol or less, or about 500 g/mol or less, or about 250 g/mol or less.

In particular examples, the first ligand is ethylenediamine, 1,3-diaminopropane, diaminocyclohexane, or diethyl ethylenediamine.

The second ligand is different from the first ligand and may also volatilize upon heating the metal complex. For example, the second ligand may release carbon dioxide, as well as volatile small organic molecules. The second ligand may be adapted to volatilize when heated without formation of a solid product. The second ligand may volatize upon heating at a temperature of, for example, 250° C. or less, or 200° C. or less, or 150° C. or less. Heating can be done in the presence or absence of oxygen. The second ligand can be anionic. The second ligand may be self-reducing.

According to certain aspects of the invention, the second ligand may be a carboxylate. The carboxylate may comprise a linear, branched or cyclic alkyl group. In one embodiment, the second ligand does not comprise an aromatic group. The second ligand may be an amide represented by —N(H)—C(O)—R, wherein R is a linear, branched or cyclic alkyl group, with 10 or fewer carbon atoms, or 9 or fewer carbon atoms, or 8 or fewer carbon atoms, or 7 or fewer carbon atoms, or 6 or fewer carbon atoms, or 5 or fewer carbon atoms. The second ligand can also be an N-containing bidentate chelator.

The molecular weight of the second ligand, including the carboxylate, may be, for example, about 1,000 g/mol or less, or about 500 g/mol or less, or about 250 g/mol, or about 150 g/mol or less or less.

In particular examples, the second ligand may be isobutyrate, oxalate, malonate, fumarate, maleate, formate, glycolate, lactate, citrate, or tartrate.

Thus, according to certain aspects of the present invention, the metal complex may comprise at least one metal, at least one first ligand, and at least one second ligand, wherein the metal may be silver, gold, or copper. Exemplary first ligands include amines and sulfur containing compounds, and exemplary second ligands include carboxylic acids, dicarboxylic acids, and tricarboxylic acids. Exemplary solvents include one or more polar protic solvents, such as at least two polar protic solvents selected from the group comprising at least water, alcohols, amines, amino alcohols, polyols, and combinations thereof.

According to certain other aspects, the metal complex may comprise at least one first metal complex having at least one first metal, at least one second metal complex having at least one second metal, at least one third metal complex having at least one third metal, and so forth, wherein each metal complex may comprise stoichiometric amounts of a metal and first and second ligands. For example, the metal complex may comprise two neutral metal complexes formed as detailed above (i.e., having stoichiometric amounts of at metal and first and second ligands).

According to certain other aspects of the present invention, the metal complex may be configured to provide a metal alloy (e.g., after curing in the textile substrate). The metal complex may comprise at least one first metal complex, wherein the first metal complex comprises a first metal and at least one first ligand and at least one second ligand, different from the first ligand; and at least one second metal complex, which is different from the first metal complex, and comprises a second metal and at least one first ligand and at least one second ligand, different from the first ligand, for the second metal; and at least one solvent. The (i) the selection of the amount of the first metal complex and the amount of the second metal complex, (ii) the selection of the first ligands and the selection of the second ligands for the first and second metals, and (iii) the selection of the solvent may be adapted to provide a homogeneous composition.

According to yet other aspects, the metal complex may comprise at least one first metal complex having at least one first metal in an oxidation state of (I), (II), (III), or (IV), and at least two ligands, wherein at least one first ligand is an amine and at least one second ligand is a carboxylate anion; at least one second metal complex, which is different from the first metal complex, wherein the second metal complex is a neutral complex comprising at least one second metal in an oxidation state of (I), (II), (III), or (IV), and at least two ligands, wherein at least one first ligand is a sulfur compound and at least one second ligand is the carboxylate anion of the first metal complex.

According to certain other aspects of the present invention, the metal complex may comprise at least one first metal complex, wherein the first metal complex is a neutral, dissymmetrical complex comprising at least one first metal in an oxidation state of (I), (II), (III), or (IV), and at least two ligands, wherein at least one first ligand is an amine and at least one second ligand is a carboxylate anion; at least one second metal complex, which is different from the first metal complex, wherein the second metal complex is a neutral, dissymmetrical complex comprising at least one second metal in an oxidation state of (I), (II), (III), or (IV), and at least two ligands, wherein at least one first ligand is sulfur compound and at least one second ligand is the carboxylate anion of the first metal complex; at least one organic solvent, and wherein the atomic percent of the first metal is about 20% to about 80% and the atomic percent of the second metal is about 20% to about 80% relative to the total metal content.

Exemplary metals for use in these metal alloys include Sc, Ti, V, Cr, Mn, Fe, Co, Ni, Cu, Zn, Y, Zr, Nb, Mo, Tc, Ru, Rh, Pd, Ag, Cd, La, Hf, Ta, W, Re, Os, Ir, Pt, Au, and Hg. In particular, coinage metals can be used including silver, gold, and copper. Precious metals can be used including gold, iridium, osmium, palladium, platinum, rhodium, ruthenium, and silver. In other preferred embodiments, platinum, nickel, cobalt, and palladium can be used. Still further, lead, iron, tin, ruthenium, rhodium, iridium, zinc, and aluminum can be used. Other metals and elements can be used as known in the art.

According to certain aspects, the first metal complex is a silver, gold, copper, platinum, nickel, iridium, or rhodium complex. For example, the first metal complex may be a silver complex. According to certain aspects, the second metal complex is a silver, gold, copper, platinum, nickel, iridium, or rhodium complex. For example, the second metal complex may be a gold complex. Examples of binary combinations of metals to form binary alloys include at least Ag—Au, Pt—Rh, Au—Cu, Zn—Cu, Pt—Cu, Ni—Al, Cu—Al, Pt—Ni, Pt—Ir, Ag—Cu, Ni—Cu, Ni—Ag, Au—Ni, and Pt—Au.

The metal complexes of the metal alloy can comprise a plurality of ligands including two or more ligands, or just two ligands. There can be, for example, a first ligand and a second ligand, different from each other. The first ligand can provide sigma electron donation, or dative bonding. The first ligand can be in a neutral state, not an anion or cation. Examples of the first ligand include amines, oxygen-containing ligands, and sulfur-containing ligands including oxygenated ethers and thioethers, including cyclic thioethers. Asymmetrical or symmetrical amines can be used. The amines can comprise, for example, at least two primary or secondary amine groups. Monodentate ligands can be used. Polydentate or multidentate ligands can be used. Alkylamine ligands can be used.

The second ligand can be different from the first ligand and can volatilize upon heating the metal complex. For example, it can release carbon dioxide, as well as volatile small organic molecules such as propene, in some embodiments. The second ligand can be a chelator with minimum number of atoms that can bear an anionic charge and provide a neutral complex. The second ligand can be anionic. For example, the second ligand can be a carboxylate, including a carboxylate comprising a small alkyl group. The number of carbon atoms in the alkyl group can be, for example, ten or less, or eight or less, or five or less. The molecular weight of the second ligand can be, for example, about 1,000 g/mol or less, or about 250 g/mol or less, or about 150 g/mole or less.

The metal complexes of the presently disclosed invention can be substantially or totally free of particles, including nanoparticles and microparticles, when in the dried state (powder) or when formulated as an ink in at least one solvent. The ink can be substantially or totally free of particles, including nanoparticles and microparticles, before deposition or printing. The ink can be substantially or totally free of particles, including nanoparticles and microparticles, after deposition but before reduction to metal (e.g., before curing). The ink can be substantially or totally free of particles, including nanoparticles and microparticles, after deposition and reduction to metal

Direct Printing

Methods known in the art can be used to deposit inks including, for example, pipetting, inkjet printing, lithography or offset printing, gravure or gravure offset printing, flexographic printing, microdispersion direct write printing, screen printing or rotary screen process printing, offset printing, stencil printing, drop casting, slot die, roll-to-roll, stamping, roll coating, spray coating, flow coating, extrusion printing, and aerosol delivery such as spraying or pneumatic or ultrasonic aerosol jet printing. One can adapt the ink formulation and the substrate with the deposition method.

In certain examples, the inks are deposited by direct printing methods such as pipetting, stencil printing, rolling, spraying, or inkjet printing. In certain example, the particle-free conductive inks are deposited using inkjet printing.

According to certain aspects, the conductive inks of the present invention are printed directly onto a surface of the textile.

According to certain aspects, certain textile substrates may benefit from pre-treating the textile, such as prewashing the textile and optionally treating by oxygen plasma, corona, and/or chemical etch (e.g., acidic, caustic). Accordingly, the conductive inks of the present invention may be printed on the textile substrate after it has been pretreated by oxygen plasma, corona, and/or chemical etch.

According to certain other aspects of the present invention, certain textile substrates may benefit from addition of a coating. For example, cellulose based substrates such as paper and/or cotton textiles may need a coating to reduce ink bleed and enhance conductivity of traces formed thereon. That is, the cellulose or cotton based substrates may be coated with a transparent layer, such as a polyurethane coating prior to printing the conductive pattern.

One can adapt the viscosity of the ink to the deposition method. For example, viscosity can be adapted for inkjet printing. Viscosity of the ink formulations measured at 25° C. can be, for example, about 500 cps or less, such as 200 cps or less, or 50 cps or less, or even 25 cps or less. Viscosity of the ink formulations measured at 25° C. can be, for example, at least 50 cps. Viscosity of the ink formulations measured at 25° C. can be, for example, about 50 cps or less, such as about 25 cps or less. According to certain other aspects, the viscosity of the ink formulations measured at 25° C. can be, for example, about 1 cps to about 20 cps, or about 1 cps to about 10 cps. Viscosity of the ink formulations may be tuned through selective ratios of polar protic solvents (e.g., ratio of water to amine).

Alternatively, the ink viscosity can be formulated, for example, to be greater than 15 cps, or 20 cps, or even 25 cps, such as by addition of binders, resins, or other additives or solids that may thicken or increase the viscosity of the ink formulation (i.e., thickeners). For example, one can adapt the concentration of dissolved solids in the ink to about 2,000 mg/ml, or 1,500 mg/ml or less, about 1,000 mg/ml or less, about 500 mg/mL or less, about 250 mg/mL or less, about 100 mg/mL or less, about 50 mg/mL or less, or about 10 mg/mL or less.

Thickeners can be added to the ink to increase the viscosity to greater than 25 cps, such as from 25 cps to 150 cps, or from 25 cps to 250 cps, or from 25 cps to 500 cps, such as would be amendable for flexographic printing. Thickeners can be added to the ink to increase the viscosity to greater than 500 cps, such as from 500 cps to 750 cps, or from 500 cps to 1000 cps, or from 500 cps to 2500 cps, such as would be amendable for screen printing.

Exemplary thickeners are known in the art and include at least high molecular weight polyacrylic acids and associative thickeners.

Other additives may be included to adapt the wetting properties of the ink. Additives such as, for example, surfactants, dispersants, colorant (e.g., dye), and/or binders can be used to control one or more ink properties as desired. For example, a hydrophilic binder may aid in wetting certain textiles, and thus may aid in providing a conductive trace that conformally coats the textile fibers (i.e., improve conductivity of the conductive trace).

The conductive ink formulations disclosed herein may include up to 20 wt. % of one or more of any of the additives indicated herein (thickeners, surfactants, colorants, etc.) additives, such as up to 15 wt. %, up to 12 wt. %, up to 10 wt. %, up to 8 wt. %, or up to 6 wt. %, or up to 4 wt. %, or up to 2 wt. %, or up to 1 wt. %, or up to 0.1 wt. %, or up to 0.05 wt. %. The compositions may include additives at from 0.01 wt. % to 20 wt. %, such as 0.01 wt. % to 15 wt. %, or from 0.01 wt. % to 12 wt. %, or from 0.01 wt. % to 10 wt. %, or from 0.01 wt. % to 8 wt. %, or from 0.01 wt. % to 6 wt. %, or from 0.01 wt. % to 4 wt. %, or from 0.01 wt. % to 3 wt. %, or from 0.01 wt. % to 2 wt. %, or from 0.01 wt. % to 1 wt. %.

According to certain aspects, the ink formulations of the present invention are substantially or totally free of additives such as thickeners, surfactants, dispersants, colorant (e.g., dye), and/or binders.

Nozzles can be used to deposit the precursor, and the nozzle diameter can be, for example, less than 200 micrometers, or even less than 100 micrometers. The absence of particulates can help with prevention of nozzle clogging. The nozzle may deposit the ink in droplets, wherein a drop size may be less than 200 micrometers, such as less than 100 micrometers, or less than 50 micrometers, or even less than 30 micrometers. The nozzle may deposit the ink in droplets, wherein a drop volume is less than 100 picoliter (pL), or less than 50 pL, or less than 25 pL, or even less than 15 pL. The drops may be deposited at a density greater than 30 drops per inch, such as greater than 60 drops per inch, or greater than 90 drops per inch, or greater than 200 drops per inch, or greater than 500 drops per inch, or greater than 1,000 drops per inch, or greater than 1,500 drops per inch, or greater than 2,500 drops per inch, or greater than 4,000 drops per inch, or greater than 6,000 drops per inch.

According to certain aspects of the present invention, the particle-free conductive inks of the present invention may be printed on textile substrates at ambient conditions, such as at standard room temperatures and pressures.

According to certain aspects of the present invention, the textile substrate may be heated before and/or during deposition of the ink. For example, the textile substrate may be heated to temperatures of 40° C. to 90° C. According to certain aspects, the platen on which the textile substrate rests during printing may be heated to temperatures of 30° C. to 90° C., such as 30° C. to 60° C., or 40° C. to 90° C. during printing.

While specific numbers are listed herein for the size and density of the droplets, volume of the droplets, and the nozzle size, these values may vary depending on the printing method chosen, the printer chosen (e.g., nozzle configuration), the viscosity of the conductive ink, and the coverage desired.

Thus, according to certain methods of the present invention, the conductive inks of the present invention may be deposited on a substrate such as a textile that is heated during deposition, followed by a curing step that converts the metal complex in the ink formulation to a metallic structure (“in situ curing”). Thus, as used herein, in situ curing may be taken to mean heating the textile during deposition of the conductive ink followed by any of the curing steps detailed herein that convert the metal complex in the ink formulation to a metallic structure.

According to certain other methods of the present invention, the conductive inks of the present invention may be deposited on a substrate such as a textile at ambient temperatures (and pressures), followed by a curing step that converts the metal complex in the ink formulation to a metallic structure (“ex situ curing”). Thus, as used herein, ex situ curing may be taken to mean that the textile is not heated during deposition of the conductive ink, and before any of the curing steps detailed herein that convert the metal complex in the ink formulation to a metallic structure.

For example, an exemplary silver ink formulation may include a silver complex having stoichiometric amounts of first and second ligands, dissolved in two or more polar protic solvents, such as water and any of an alcohol and/or amine. Generally, such an ink solution is formulated to include the silver complex at 250 mg/ml or greater, such as 500 mg/ml. These solutions are clear. Heating the textile during deposition of the conductive ink may reduce the ink bleed outside of the printed region. For example, the conductive traces formed using the inks and methods of the present invention may exhibit an ink bleed of less than 0.5 mm, such as less than 0.4 mm, or less than 0.3 mm, or less than 0.2 mm, or even less than 0.1 mm. As used herein, the term “ink bleed” may be taken to mean a measure of the precision of the ink deposition and is referred to in terms of the distance from a defined edge (intended border) of a printed trace that the ink may extend.

An exemplary solution of 500 mg/ml of an ink composition according to aspects of the present invention may have a viscosity of about 5-15 cps at 25° C., a density of about 1.0-1.3 g/mL, a pH of at least 10-13, a surface tension of about 15-34 dyne/cm, and a silver content of about 15-25 wt. %. Ink jet printing of such an ink may include depositing the ink as droplets of between 5-200 micrometers at 60-6,000 drops per inch to a textile substrate heated at between 30° C. to 90° C. on the platen, such as 65 micrometers at 1270 drops per inch. The textile may then be cured at a temperature of less than 200° C. for a time of less than 30 minutes, such as for between 2-20 minutes at 140° C., or 10 minutes at 140° C. Alternatively, the textile may be cured by exposure to infrared radiation for a time of less than 30 minutes, such as for between 2-20 minutes, or 10 minutes. An exemplary line wide resulting from this method may about 2 mm and may show an ink bleed of less than 0.5 mm, such as less than 0.2 mm, or even less than 0.1 mm. Moreover, the pattern demonstrated a resistivity of less than 10Ω/□, such as less than 5 Ω/□, or less than 1Ω/□, or from 0.1 Ω/□ to 0.9 Ω/□.

According to certain aspects, the conductive traces of the presently disclosed invention may have sheet resistance values of less than 10.0Ω/□, or less than 8.0Ω/□, or less than 6.0Ω/□, or less than 4.0Ω/□, or less than 2.0Ω/□, or less than 1.0Ω/□, such as from 0.1Ω/□ to 1.0Ω/□. Certain applications of the conductive traces may benefit from increased sheet resistance, such as more than 2.0Ω/□ or 10.0Ω/□, such as resistive heaters.

Exemplary systems that may be used in methods of the presently disclosed invention include FujiFilm Dimatix DMP 2850 and DMP 2931. Using this printer, the particle-free conductive inks of the present invention may be printed to textiles pre-heated on the platen using a drop size of 5-200 micrometers, or a drop volume of less than 100 pL, at 60-6,000 drops per inch. The textile may then be cured on the platen in the device, such as for 10 minutes at 140° C. or 10 minutes exposure to infrared radiation or removed to an oven or other area for curing, wherein the metal in the metal complex turns to a solid conductive metal. Curing may be by any method disclosed herein.

Key factors affecting the conductivity achievable by the presently disclosed inks and printing methods include compatibility of the ink chemistry with the surface energy of the textile, the textile size and structure (woven, non-woven), pretreatment of the textile, such as with O₂ plasma, and the curing methods, such as the in situ heating of the textile during printing which provides high resolution traces, and the low temperature curing (<200° C.; see section below regarding curing). Thus, the presently disclosed inks and methods provide a large advantage over the prior art inks, wherein the particles of the ink may clog the nozzles of an inkjet device, and traces formed using the inks are generally non-conductive (i.e., show very high sheet resistance) and non-compatible with many textiles as they require high cure temperatures.

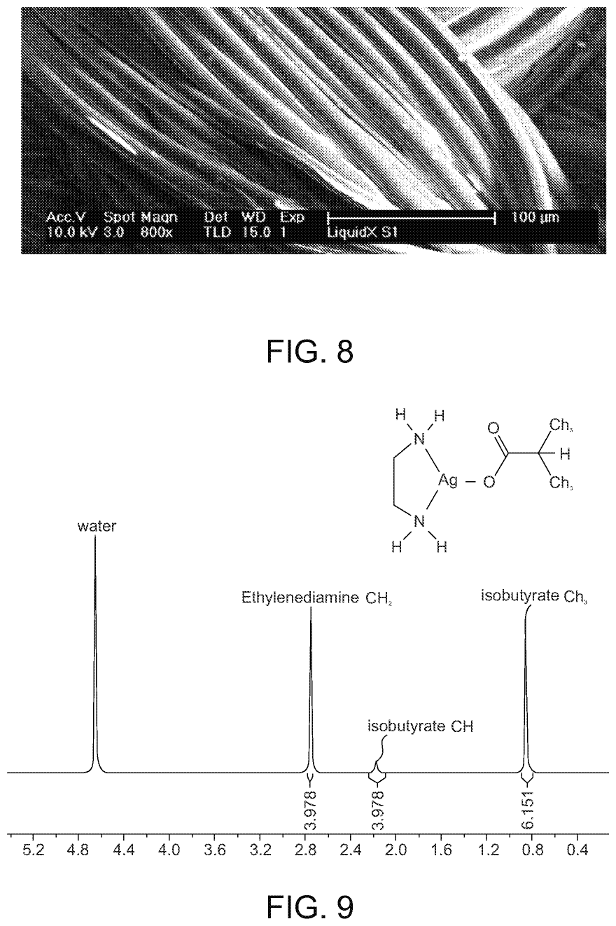

Shown in FIG. 8 is a close-up view of a woven textile substrate printed with the presently disclosed particle-free conductive ink, wherein the printing was on a heated substrate (in situ heat cure). Prior art conductive inks, which comprise particles (nanoparticles, flakes, etc.), would not be able to penetrate the textile and were found to sit on top of the textile substrate.

The present inventors have found that the sheet resistance values for textiles (knit, woven, and nonwoven such as Evolon®) printed with the particle-free conductive inks according to the present invention using in situ curing is improved over ex situ curing for most textile substrates. The in situ curing lowers the sheet resistance, in some cases several orders of magnitude over values measured from ex situ cured conductive traces, and also reduces the ink bleed. These results were consistent for all numbers of printed layers tested (number of layers in the conductive trace). Thus, methods of the presently disclosed invention, which include heating of the textile during deposition of the ink, such as by inkjet printing, not only leads to improved trace resolution, but also improved conductivity of the trace.

Additionally, the sheet resistance values for knit and non-woven (Evolon®) textiles printed with the particle-free conductive inks according to the present invention were improved by pretreatment by oxygen plasma or corona. Accordingly, methods of the presently disclosed invention, which include heating of the textile before and/or during deposition of the ink, such as by ink jet printing, may also include pretreatment of the textile, and may provide improved conductivity of the trace over untreated textiles.

Curing the Particle-Free Conductive Inks

Once the particle-free conductive ink formulations have been printed onto a substrate, such as a textile substrate, at either ambient temperatures or elevated temperatures, they may be cured to form the conductive pattern (i.e., converted to a metallic structure). Curing can include heating the printed substrate, and/or irradiating the printed substrate. In certain examples, the printed substrate may be cured by heating to a temperature of 200° C. or less, such as 150° C. or less, or 100° C. or less, for a time period of less than 60 minutes, such as less than 30 minutes, or less than 15 minutes. In a particular example, the printed substrate is heated to 140° C. for 10 minutes, or exposed to infrared radiation for 10 minutes, to form a conductive pattern with a resistance of less than 1 Ω/□.

In certain examples, the conductive trace on the textile substrate may be additionally, or alternatively, cured by exposure to pulsed light, such as by photonic curing, wherein the number of pulses ranges from 2 to 20. Alternatively, or in addition, curing may include irradiating the conductive trace on the textile substrate, such as by exposure to infrared radiation.

Protective Coatings

According to certain aspects of the present invention, the electron donating layer may be at least partially coated with a protective coating. For example, all or a portion of the electron donating layer may be coated with a polymer coating, such as an adhesive, flexible polymer film that may provide wash durability and/or abrasion resistance. Thus, polymer films that provide a balance of hardness and flexibility are preferred. Suitable coatings may be comprised of polyurethane film formers and may be waterborne or solvent based.

The protective coating can be deposited by painting, spraying, or printing (e.g., inkjet printing). The viscosity of the polymeric solutions can be adjusted for the specific textile and deposition method by dilution with appropriate solvents and solvent mixtures. Such coatings may be cured by heat treatment, evaporation of solvents, irradiation (e.g., UV treatment), or any combination thereof. An exemplary coating includes an acrylic-based coating that is printed over the conductive trace and is cured by heating the textile to 160° C. or less, such as 150° C. or less for 30 minutes or less, such as 20 minutes or less.

The coatings may improve washability of the conductive traces and may also improve abrasion resistance of the conductive traces.

Additional coatings may be provided over contact regions, such as at the contact points or pads of a trace. Such coatings may include conductive polymers and may provide conductive contact with the printed trace while also protecting the trace from abrasion and/or during wash cycles.

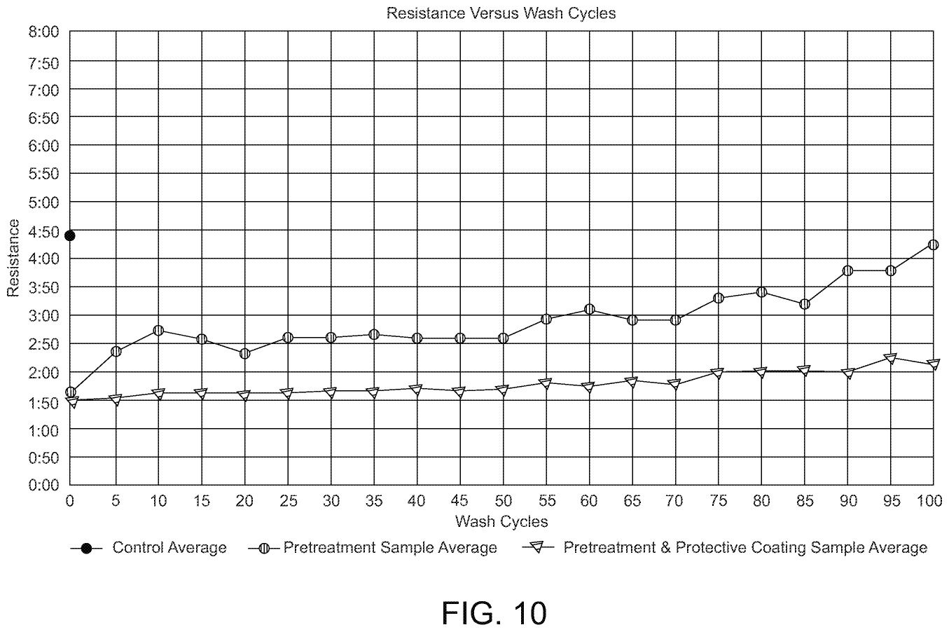

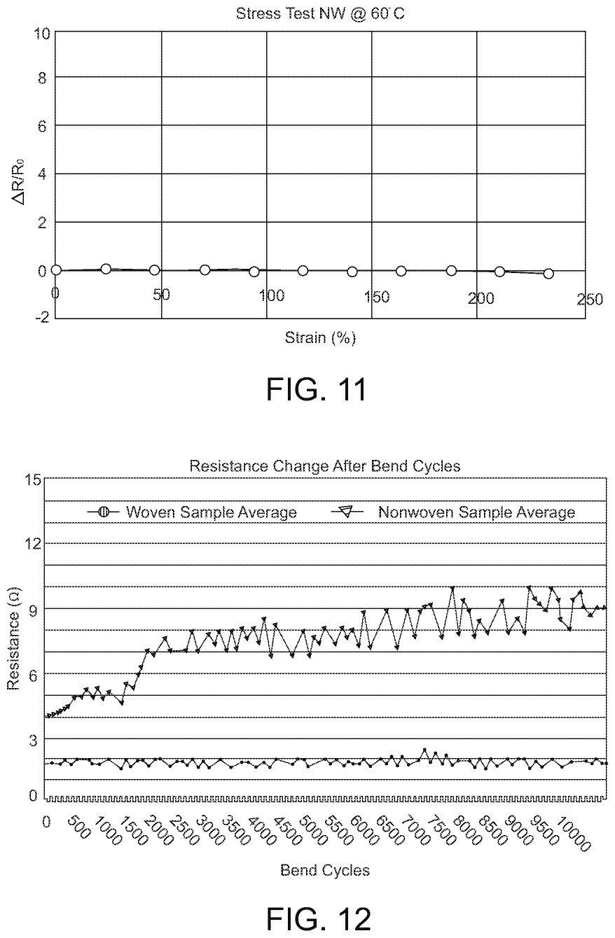

Thus, the inventive TENGs disclosed herein are found to have excellent wear performance, e.g., bendability, washability, strain resistance, etc. For example, the conductive patterns on the fabric substrate may withstand at least 50 wash cycles, such as at least 70 wash cycles, or even 100 wash cycles with air drying (see FIG. 10 and examples). For example, the resistance of the conductive traces formed using the inks and methods of the present invention may increase only slightly after multiple wash cycles, such as by less than 50% after 50 washes, or less than 30% after 50 washes, or less than 15% after 50 washes, or less than 70% after 100 washes, or less than 60% after 100 washes, or less than 40% after 100 washes, or less than 30% after 100 washes, or less than 20% after 100 washes, wherein a wash cycle is defined as in according to AATCC 61-2013 (laundering). As shown in FIG. 11, the protective coating may improve the washability of the TENGs disclosed herein.

The TENGs may be abrasion resistant (up to 500 cycles by standard ASTM testing methods) and may be sweat resistant (moisture resistant).

The TENGs may be strain resistant. For example, TENGs provided on knit textiles may be stretched by up to 50%, or up to 100%, without connection loss, generally showing a small increase in conductivity with an increase in stretching of the textile substrate (see FIG. 11 and examples).

The TENGs may be bendable, showing less than a 10% loss in conductivity after up to 10,000 bend cycles using standard ASTM testing methods (see FIG. 12).

### EXAMPLES

Production of Triboelectric Energy Generators

TENGs according to the presently disclosed invention are provided on woven polyester (PE) fabric having dimension of 2 inches×2 inches. The electron donating material is a particle-free conductive silver ink as disclosed herein. In certain examples a protective coating, such as an abrasion resistant coating, is provided over the silver film. The electron accepting material is a layer of KAPTON® (polyimide film, 0.003 inches thick) or a layer of PDMS, and the gap distance is maintained using a nylon mesh fabric.

TABLE 1

| | | | | Electrical Measurements | | |
|---|---|---|---|---|---|---|
| | Device Construction | | | Volt | Volt | |
| Example | Layer 1 | Refer to: | Layer 2 | Max | Min | μAmp |
| 1 | PE w/printed Ag | FIG. 2 | PE w/printed Ag and | 29 | −5 | 0.6 |
| | | | PDMS surface | | | |
| 2 | PE w/printed Ag | FIG. 3 | PE w/printed Ag and | 36 | −7 | 0.5 |
| | | | PDMS surface | | | |
| 3 | PE w/printed Ag | FIG. 4 | PE w/printed Ag and | 38 | −6 | 0.5 |
| | | | PDMS surface | | | |
| 4 | PE w/printed Ag and | FIG. 3 | PE w/printed Ag and | 118 | −30 | 1.5 |
| | protective coating | | PDMS surface | | | |
| 5 | PE w/printed Ag and | FIG. 5 | PE w/printed Ag and | 70 | −16 | 1.0 |
| | protective coating | | PDMS surface | | | |
| 6 | PE w/printed Ag and | FIG. 6 | PE w/printed Ag and | 64 | −22 | 0.9 |
| | protective coating | | PDMS surface | | | |
| 7 | PE w/printed Ag and | FIG. 7 | PE w/printed Ag and | 32 | −10 | 0.4 |
| | protective coating | | PDMS surface | | | |
| 8 | PE w/printed Ag and | FIG. 8 | PE w/printed Ag and | 88 | −30 | 1.4 |
| | protective coating | | PDMS surface | | | |
| 9 | PE w/printed Ag and | FIG. 8 | PE w/printed Ag and | 86 | −24 | 2.1 |
| | protective coating | | PDMS surface | | | |
| 10 | Kapton film w/printed Ag | FIG. 7 | PE w/printed Ag and | 30 | −14 | 1.0 |
| | | | PDMS surface | | | |
| 11 | PET film w/printed Ag | FIG. 7 | PE w/printed Ag and | 74 | −24 | 1.0 |
| | | | PDMS surface | | | |
| 12 | BR6832 w/printed Ag | FIG. 3 | PE w/printed Ag and | 112 | −36 | 1.6 |
| | | | PDMS surface | | | |
| 13 | BR6818 w/printed Ag | FIG. 3 | PE w/printed Ag and | 144 | −24 | 0.4 |
| | | | PDMS surface | | | |
| 14 | BR6818 w/printed Ag and | FIG. 3 | PE w/printed Ag and | 158 | −28 | 1.8 |
| | protective coating | | PDMS surface | | | |
| 15 | BR4008 w/printed Ag and | FIG. 3 | PE w/printed Ag and | 144 | −52 | 2.7 |
| | protective coating | | PDMS surface | | | |
| 16 | BR6818 w/printed Ag and | FIG. 3 | BR6818 w/printed Ag and | 116 | −20 | 2.6 |
| | protective coating | | PDMS surface | | | |
| 17 | BR4008 w/printed Ag and | FIG. 3 | BR6818 w/printed Ag and | 124 | −24 | 2.0 |
| | protective coating | | PDMS surface | | | |
| 18 | PE w/printed Ag and | FIG. 3 | BR6818 w/printed Ag and | 108 | −32 | 1.4 |
| | protective coating | | PDMS surface | | | |
| 19 | BR4008 w/printed Ag and | FIG. 3 | BR4008 w/printed Ag and | 108 | −24 | 1.4 |
| | protective coating | | PDMS surface | | | |
| 20 | BR6818 w/printed Ag and | FIG. 3 | BR4008 w/printed Ag and | 108 | −20 | 2.2 |
| | protective coating | | PDMS surface | | | |
| 21 | PE w/printed Ag and | FIG. 3 | BR4008 w/printed Ag r | 112 | −24 | 2.0 |
| | protective coating | | and PDMS surface | | | |
| 22 | BR6818 w/printed Ag and | FIG. 7 | BR6818 w/printed Ag and | 216 | −52 | 2.4 |
| | protective coating | | PDMS surface | | | |
| 23 | BR4008 w/printed Ag and | FIG. 7 | BR6818 w/printed Ag and | 228 | −68 | 2.1 |
| | protective coating | | PDMS surface | | | |
| 24 | BR4008 w/printed Ag and | FIG. 7 | BR4008 w/printed Ag and | 144 | −32 | 1.3 |
| | protective coating | | PDMS surface | | | |
| 25 | BR6818 w/printed Ag and | FIG. 7 | BR4008 w/printed Ag and | 152 | −36 | 1.4 |
| | protective coating | | PDMS surface | | | |
| 26 | BR4008 w/printed Ag and | FIG. 7 | PE w/printed Ag and | 196 | −28 | 2.0 |
| | protective coating | | PDMS surface | | | |

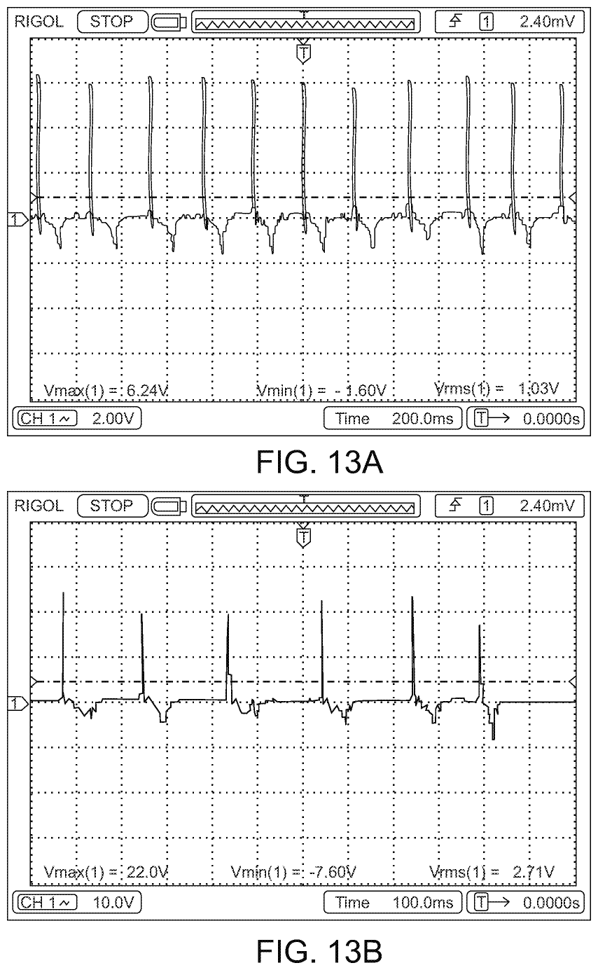

As shown in Table 1, voltage max, voltage min, and current were tested for several different TENG arrangements according to the presently disclosed invention. Note: BR4008 is a nonwoven fabric from Ahlstrom Munksjo (40 g/m², 152μ thickness), BR6818 is a nonwoven fabric from Ahlstrom Munksjo (25 g/m², 95μ thickness), and BR6832 is a nonwoven fabric from Ahlstrom Munksjo (20 g/m², 96μ thickness). Voltage max and min are measured with a Rigol DS1102e oscilloscope, and the current are measured with a Klien Tools MM600 digital multimeter. Exemplary oscilloscope measurements are shown in FIGS. 13A and 13B.

Exemplary Systems Comprising a Triboelectric Energy Generator

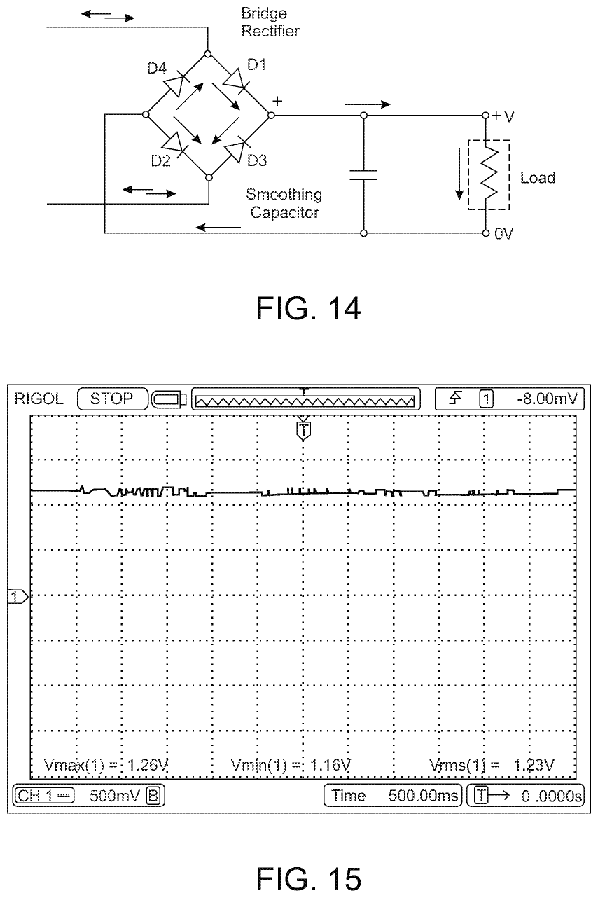

A system that may provide power to an electronic device is illustrated in FIG. 14. As shown, the system comprises a TENG, such as described hereinabove, that may provide energy to a component consisting of a full wave bridge rectifier, comprising four diodes, D1-D4, and a smoothing capacitor. The resulting system converts the pulse alternating voltage shown in FIGS. 13A and 13B to a non-alternating continuous voltage, as shown in FIG. 15, which may be used to power an electronic device or charge a battery.

The diodes D1-D4 used in this example are Schottky Diodes BAT46 and the smoothing capacitor has a capacitance of 4.7 μf. The applied load is 10 megaohms. The maximum and minimum voltages are 1.26 and 1.16, respectively.

In another example, the triboelectric energy generator may be integrated with an energy harvesting battery charger, such as the LTC 3331 available from Linear Technology Corporation, to create an energy supply for various applications, such as personal smart fabrics comprising wearable, mobile, biomedical sensors providing real-time breath and heartbeat information.

In another example, the triboelectric energy generator system may power field data recorders to log temperature, atmospheric pressure and humidity in remote locations.

In yet another example, the triboelectric energy generator system may be integrated with an energy harvesting power supply, such as the LTC 3588 available from Linear Technology Corporation, to store the energy in a capacitor and release the energy as needed to a device at a selected voltage. The harvested energy may be used to illuminate an LED bulb or activate a liquid crystal display.

Production of a Particle-Free Conductive Ink

Exemplary conductive inks useful for printing the electron donating material include conductive particle-free silver inks. Such inks comprise silver complexes comprising a carboxylate ligand (e.g., silver carboxylate), which may be formed by reaction of a metal oxide or metal-acetate and a carboxylic acid in a reaction that affords analytically pure compounds and proceeds in quantitative yields.

As example, silver acetate was reacted with a carboxylic acid (isobutyrate and cyclopropate). The elemental analysis of the two silver complexes were C, 24.59; H, 3.72 and C, 24.68; H, 2.56 for the isobutyrate and cyclopropate, respectively. Theoretical values are C, 24.64; H, 3.62 and C, 24.90; H, 2.61 for the isobutyrate and cyclopropate, respectively.

The metal-second ligand salt (e.g., silver carboxylate) was then reacted with an excess of a first ligand to form the metal complex. In a typical preparation, silver isobutyrate was prepared as described above, and placed in a 25 mL one-neck 14/20 round bottom flask containing a Teflon coated magnetic stir bar. To this was added 13 eq. ethylenediamine (amounts as shown in Table 2 below).

The reaction proceeded for 2 h at room temperature with stirring, was filtered to remove any particulates, and the unreacted ethylenediamine was removed by rotary evaporation at 40° C. to yield a white powder. Additional wash steps can be included. The isolated metal complex—ethylenediamine silver isobutyrate—was then dissolved to at least 100 mg/ml in a mixture of polar protic solvents (water, propylene glycol, and isopropanol) to form a particle-free conductive ink which is clear (see top right of FIG. 9, and Table 3 below).

TABLE 2

| Diamine Amount | Silver (I) Carboxylate Amount | |
|---|---|---|
| (ethylenediamine) | (silver isobutyrate) | Yield |
| 184 g, | 46 g, | 59 g |
| 3059 mmol, | 235 mmol, | (99%) |
| 13equiv. | 1 equiv. | |

TABLE 3

| Isolated Metal Complex | Water | Propylene glycol | Isopropanol |
|---|---|---|---|
| 2.20 g | 3.08 g | 0.77 g | 1.25 g |
| (30%) | (42%) | (11%) | (17%) |

Purity of the Metal Complex

Preparation of the metal complexes was found to require an excess of the first ligand reactant with the metal-second ligand (see table above; 13-fold excess second ligand used to produce the metal complex). As example, most silver (I) carboxylates are insoluble in most conventional solvents. A 1:1 reaction (1:1 silver isobutyrate:ethylenediamine) gave a dark colored product with a large amount of insoluble material, presumably unreacted silver (I) isobutyrate, when formulated in a polar protic solvent system. Thus, the metal complexes formed by the 1:1 reaction likely failed to promote complete conversion of all reactants to products and failed to form continuous conductive films on a substrate.

A 1:6 reaction (1:6 silver isobutyrate:ethylenediamine), on the other hand, formed crystals spontaneously from a filtered solution of the reaction. Moreover, while the metal complex did dissolve in the polar protic solvent system, the presence of excess unreacted diamine was found to have a significant impact on the density, viscosity, and surface tension of the ink formulations. The 1:6 product formulated as an ink shows poor sheet coverage and extremely high sheet resistance (>600,000Ω/□).

The 1:13 reaction product listed in the table above, which was purified to remove excess unreacted amine (first ligand) showed excellent sheet coverage and demonstrated a sheet resistance of less than 1Ω/□. The purified product, dissolved in a polar protic solvent system as shown in the table above, showed a density of 1.12 g/mL, a viscosity of 8.55 cps, and a surface tension of 22.9 dyne/cm.

Accordingly, an important step in producing the particle-free conductive inks of the present invention is removal of any unreacted second ligand, especially in view of the large excess used to formulate the final metal complex. When purified as detailed above, the product (yield 99%) is colorless. Unpurified products, however, tend to be dark colored, which is likely associated with normal darkening of diamines when exposed to open air. In general, amines absorb moisture and carbon dioxide resulting in formation of unstable carbamates. Such speciation of amines may destabilize diamine-silver (I) carboxylates, which often results in premature silver metallization, dark coloration and particle formation. Hence, removal of any residual amines is important to promote stability of diamine-silver (I) carboxylates, especially if concomitant preparation of zero-particulate diamine-silver (I) carboxylate compositions is required.

Stoichiometric Ratio of Ligands and Metal in the Metal Complex

The metal complex was found to comprise stoichiometric amounts of the first and second ligands and the metal. Structural analysis using proton NMR showed that the ethylenediamine silver isobutyrate powder dissolved in D₂O consists of stoichiometric amounts of the ethylenediamine ligand coordinated to silver isobutyrate. A ¹H-NMR spectrum of the metal complex in D₂O (see FIG. 9; ¹H-NMR scan on a Bruker AV-360 spectrometer) showed the expected three proton-carbon (CH) peaks: 1 for the two ethylenediamine CH₂ groups (4 protons total), 1 for the single isobutyrate CH group (1 proton), and 1 for the two isobutyrate CH₃ groups (6 protons total). These were assigned as: 0.93 ppm isobutyrate CH₃, 2.25 ppm isobutyrate CH, and 2.81 ppm ethylenediamine CH₂. The proton integral ratio of 3.978 ethylenediamine CH₂:0.928 isobutyrate CH:6.151 isobutyrate CH₃ is consistent with 1 ethylenediamine: 1 silver isobutyrate, or stoichiometric amounts of the metal, and each of the ethylenediamine and isobutyrate ligands.

In order to verify that the metal complex, when dissolved in two or more polar protic solvents to form the ink, maintains a stoichiometric ratio of the first and second ligands and the metal, further ¹H-NMR experiments were performed for the metal complex dissolved in a mixture of three polar protic solvents as listed above (water, propylene glycol, isopropanol), and D₂O. The obtained spectra demonstrated well-resolved peaks for the various polar protic solvents as well as the metal complex (ethylenediamine silver (I) isobutyrate), which are assigned as: 0.93 ppm (doublet, isobutyrate CH₃), 2.25 ppm (septet, isobutyrate CH), and 2.81 ppm (singlet, ethylenediamine CH₂).

The strong similarity between the chemical shifts of the metal complex in the NMR solvent (FIG. 9) and in the composition comprising the metal complex and two or more polar protic solvents suggests excellent compatibility between the metal complex and the polar protic solvent system. The ethylenediamine silver (I) isobutyrate proton ratios of 4.098 ethylenediamine CH₂:0.944 isobutyrate CH:6.446 isobutyrate CH₃ are in good agreement with theoretical ratios of 4 ethylenediamine CH₂: 1 isobutyrate CH:6 isobutyrate CH₃; which demonstrates that dissolving the metal complex in a polar protic solvent carrier does not impact the coordination environment around the metal (i.e., silver). This result further corroborates the fact that the chemical composition of the metal complex remains unchanged when dissolved to form the ink composition (i.e., stoichiometry remains unchanged).

Formulation of Particle-Free Conductive Inks

Various polar protic solvents systems were tested to demonstrate the flexibility of the solvent choice for formulation of the particle-free conductive inks of the present invention (see Tables 4 and 5 below). For example, a diamine silver (I) isobutyrate complex was formulated in solvent systems comprising at least two polar protic solvents. Representative ink formulations using different combinations of polar protic solvents, and data showing that the ink formulations produce continuous, highly conductive films (sheet resistance of 0.04-0.09Ω/□) when formulated in the polar protic solvents are shown in Tables 4 and 5 below.

Washability of Particle-Free Conductive Inks

The particle-free conductive inks of the presently disclosed invention were printed on various textiles to form conductive traces using ink jet printing methods as disclosed hereinabove. The trace remained uncoated or was coated with a transparent UV curable polyurethane coating. Sheet resistance for these patterns was tested according to AATCC 61-2013 (laundering). As shown in FIG. 10, very little change in the conductivity for the traces was observed after up to 50 washes. The coated trace shows good conductivity after as many as 100 wash cycles, while the native (uncoated) traces showed good conductivity after as many as 70 wash cycles. The control samples completely lost conductivity after only 5 wash cycles.

Analysis of various textiles according to AATCC 61-2013 demonstrated that a conductive trace comprising 8 layers of printed ink showed less than a 3Ω increase in resistance after 100 wash cycles. When a protective coating such as any of the abrasion resistant coatings disclosed herein was included over the trace, the resistance only increased by less than 0.7Ω.

TABLE 4
Metal Complex Formulated in Polar Protic Solvent Systems

| | | | Glycol | | Glycol | | |
|---|---|---|---|---|---|---|---|
| | metal | | ethylene | propylene | ether | Alcohol | |
| composition | complex | water | glycol | glycol | (dowanol) | ethanol | isopropanol |
| A | 2.20 g | 3.08 g | — | 0.77 g | — | — | 1.25 g |
| B | 2.01 g | — | — | 0.77 g | — | — | 4.25 g |
| C | 2.03 g | 4.27 g | — | 0.78 g | — | — | — |
| D | 2.03 g | 4.26 g | 0.75 g | — | — | — | — |
| E | 2.00 g | 3.00 g | — | 0.27 g | — | — | 1.75 g |
| F | 2.01 g | 3.07 g | — | 0.13 g | — | — | 1.91 g |
| G | 2.00 g | 3.06 g | — | 1.5 g | — | — | 0.51 g |
| H | 2.00 g | 3.02 g | 0.75 g | — | — | — | 1.26 g |
| I | 2.02 g | 3.03 g | — | 0.76 g | — | 1.26 g | — |
| J | 2.04 g | 3.03 g | — | 0.76 g | 1.26 g | — | — |
| K | 2.09 g | 3.01 g | — | 0.51 g | 0.76 g | | 0.76 g |

TABLE 5

| | Density | Viscosity | Surface Tension | Sheet Resistance |
|---|---|---|---|---|
| composition | (g/mL) | (cP) | (dyne/cm) | (Ω/□) |
| A | 1.12 | 8.55 | 22.9 | 0.05 |
| B | 0.937 | 10.8 | 23.3 | 0.04 |
| C | 1.15 | 4.60 | 25.3 | 0.08 |
| D | 1.15 | 3.77 | 24.7 | 0.08-0.09 |
| E | 1.09 | 6.99 | 23.6 | 0.06 |
| F | 1.08 | 6.71 | 22.7 | 0.06 |
| G | 1.14 | 8.83 | 23.3 | 0.05 |
| H | 1.11 | 7.02 | 23.5 | 0.08 |
| I | 1.11 | 21.3 | 23.8 | 0.06 |
| J | 1.14 | 8.25 | 23.5 | 0.9-01 |
| K | 1.12 | 8.21 | 22.7 | 005-0.06 |

Strain Resistance

Woven fabrics were printed using inks and methods according to the presently disclosed invention and subjected to strain resistance measurements. Shown in FIG. 11 are results for electromechanical stretch testing under various amounts of stretching (0% to 230%). For conductive traces of the prior art, strain induces film cracking which reduces conductivity. Using inks and methods according to the present invention, the trace conductivity was little affected by the increased strain until the breakpoint of the textile (i.e., textile rips into two pieces). This unusual behavior is demonstrated by a very slight increase in the average spot temperature of the trace (as measured using FUR; data not shown), where the spot temperature correlates to the amount of heat generated when electrons flow through a stretched conductive fabric; the higher the temperature, the more heated generated by the flowing electrons.

Bendability of the printed traces was also tested, as shown in FIG. 12, and only a small loss of conductivity (<10%) was observed for bending of a conductive trace printed on woven textiles using inks and methods of the present invention (10,000× bends in the trace; tested according to ASTM D522-Mandel Bend Test). Nonwoven textiles showed reduced performance after 1,300 bends, which is likely a function of breakdown of the textile and not the conductive trace.

Abrasion Resistance

A woven substrate was printed with a conductive ink according to the present invention, and coated with an ablation resistance coating (Ablative Resistant Coating NSN 8030-00-164-4389) or left uncoated. Sheet resistance was measured for several textile samples after coating (control), 10×, 20×, and 30× rubbing (see Table 6).

TABLE 6

| | Resistance Ω | | | | |
|---|---|---|---|---|---|
| | Before | After | After | After | After |
| Sample | coating | coating | rubbing 10X | rubbing 20X | rubbing 30X |
| Uncoated | 6-8 | — | 62-101 | 132-138 | 300-382 |
| Coated | 6-8 | 6-7 | 9-10 | 11-12 | 12-13 |

Aspects of the Invention

The following aspects of the present invention are disclosed in this application:

Aspect 1. A triboelectric energy generator comprising: a first flexible layer having a first electron donating material coated on at least a first surface and an electron accepting material coated over the first electron donating material; and a second flexible layer having a second electron donating material coated on at least a first surface, wherein the first and second layers are positioned adjacent each other with their first surfaces facing inward toward each other and separated by a gap distance, and wherein an electric potential is generated upon movement between the first and second flexible layers, wherein the movement is at least alternating contact and no-contact between the first and second flexible layers.

Aspect 2. The triboelectric energy generator according to any preceding aspect, wherein the first and/or second flexible layers are textile layers, wherein each textile layer is independently selected from a knit, woven, or nonwoven fabric comprising fibers of polyester, polyamide, spandex, nylon, Evolon®, elastane, cotton, cellulose, silk, wood, wool, or blends thereof.

Aspect 3. The triboelectric energy generator according to any preceding aspect, wherein the first and/or second electron donating material comprises a conductive metal film deposited by a particle-free metal ink.

Aspect 4. The triboelectric energy generator according to any preceding aspect, wherein the particle-free metal ink comprises copper, silver, gold, or nickel.

Aspect 5. The triboelectric energy generator according to any preceding aspect, wherein the particle-free conductive metal ink conformally coats fibers of the textile of the first and/or second flexible layer.

Aspect 6. The triboelectric energy generator according to any preceding aspect, wherein the particle-free metal ink of the first and/or second electron donating materials is deposited by a particle-free silver ink that conformally coats fibers of the textile layer.

Aspect 7. The triboelectric energy generator according to any preceding aspect, wherein the gap distance is about 0.01 mm to about 5 mm, such as 0.1 mm to about 2 mm.

Aspect 8. The triboelectric energy generator according to any preceding aspect, wherein a work function of the electron accepting material is at least 3 eV greater than a work function of the electron donating material.

Aspect 9. The triboelectric energy generator according to any preceding aspect, wherein the electron accepting material comprises a flexible polymeric material such as polyimide, and elastomeric materials, such as polydimethylsiloxane (PDMS) or silicone rubber.

Aspect 10. The triboelectric energy generator according to any preceding aspect, further comprising a third flexible layer positioned within the gap between the first and second flexible layers.

Aspect 11. The triboelectric energy generator according to any preceding aspect, wherein the third flexible layer comprises a mesh material having at least a 60% open area, such as at least an 80% open area.

Aspect 12. The triboelectric energy generator according to any preceding aspect, wherein the mesh material comprises a flexible polymeric material, such as nylon.

Aspect 13. The triboelectric energy generator according to any preceding aspect, further comprising a protective coating such as an abrasion resistant coating over either or both of the first and second electron donating material.

Aspect 14. The triboelectric energy generator according to any preceding aspect, wherein the second flexible layer comprises a raised pattern formed by thermoforming or embossing, wherein a depth of the raised pattern defines the gap distance.

Aspect 15. A triboelectric energy generator comprising: a first flexible layer having a first electron accepting material coated on at least a first surface; a second flexible layer having a second electron accepting material coated on at least a first surface; and a third flexible layer comprising an electron donating material, wherein the electron donating material comprises a conductive metal film deposited by a particle-free metal ink, wherein the first and second layers are positioned adjacent each other with their first surfaces facing inward toward each other with the third flexible layer positioned therebetween, wherein each of the flexible layers are separated by a gap distance, and wherein an electric potential is generated upon movement between the first, second, and third flexible layers, wherein the movement is at least alternating contact and no-contact between the first and third flexible layers, and the third and second flexible layers.

Aspect 16. The triboelectric energy generator according to aspect 15, wherein the first, second, and third flexible layers are textile layers, wherein each textile layer is independently selected from a knit, woven, or nonwoven fabric comprising fibers of polyester, polyamides, spandex, nylon, Evolon®, elastane, cotton, cellulose, silk, wood, wool, or blends thereof.

Aspect 17. The triboelectric energy generator according to aspect 15 or 16, wherein the particle-free metal ink comprises copper, silver, gold, or nickel.

Aspect 18. The triboelectric energy generator according to any one of aspects 15 to 17, wherein the particle-free metal ink conformally coats fibers of the third flexible layer.

Aspect 19. The triboelectric energy generator according to any one of aspects 15 to 18, wherein the gap distance is about 0.01 mm to about 5 mm, such as 0.1 mm to about 2 mm.

Aspect 20. The triboelectric energy generator according to any one of aspects 15 to 19, wherein a work function of the electron accepting material is at least 3 eV greater than a work function of the electron donating material.

Aspect 21. The triboelectric energy generator according to any one of aspects 15 to 20, wherein the electron accepting material comprises a flexible polymeric material such as polyimide, and elastomeric materials, such as polydimethylsiloxane (PDMS) or silicone rubber.

Aspect 22. The triboelectric energy generator according to any one of aspects 15 to 21, further comprising a protective coating such as an abrasion resistant coating over the electron donating material of the third flexible layer.

Aspect 23. The triboelectric energy generator according to any one of aspects 15 to 22, wherein the third flexible layer comprising the electron donating material has a raised pattern formed by thermoforming or embossing, wherein a depth of the raised pattern defines the gap distance.

Aspect 24. The triboelectric energy generator according to any one of aspects 15 to 23, wherein either or both of the first and second flexible layers further comprise an electron donating material on at least the first surface, wherein the electron accepting material is coated over the electron donating material.

Aspect 25. The triboelectric energy generator according to aspect 24, wherein the electron donating material comprises a conductive metal film deposited by a particle-free metal ink.

Aspect 26. The triboelectric energy generator according to aspect 25, wherein the particle-free metal ink comprises copper, silver, gold, or nickel.

Aspect 27. A method for forming a triboelectric energy generator in a flexible substrate, the method comprising: depositing an electron donating material on at least a first side of a first flexible substrate; coating the electron donating material on the first side of the first flexible substrate with an electron accepting material; depositing a second electron donating material on at least a first side of a second flexible substrate; and positioning the first and second flexible substrates adjacent each other with their first surfaces facing inward toward each other and separated by a gap distance, wherein an electric potential is generated upon movement between the first and second flexible layers.

Aspect 28. The method according to aspect 27, further comprising depositing a second electron accepting material over the second electron donating material on the second flexible substrate; depositing an electron donating material on a third flexible substrate; and placing the third flexible substrate between the first and second flexible substrates with their first sides facing inward toward the third flexible substrate.

Aspect 29. A method for forming a triboelectric energy generator in a flexible substrate, the method comprising: depositing an electron donating material on a third flexible substrate; placing the third flexible substrate between first and second additional flexible substrates, each having an electron accepting material facing inward toward the third flexible substrate and separated by a gap distance therefrom, wherein an electric potential is generated upon movement between the flexible layers.

Aspect 30. The method according to aspect 29, further comprising: depositing an electron donating material on first sides of the first and second flexible substrates; and coating the electron donating material with the electron accepting material, wherein the first sides of the first and second flexible layers face inward toward the third flexible substrate.

Aspect 31. The method according to any preceding method aspect, wherein any of the electron donating materials comprise a conductive metal film deposited by a particle-free metal ink.

Aspect 32. The method according to any preceding method aspect, wherein any of the electron accepting materials comprise a flexible polymeric material such as polyimide, or an elastomeric material, such as polydimethylsiloxane (PDMS) or silicone rubber.

Aspect 33. The method according to any preceding method aspect, further comprising after depositing the particle-free conductive ink, reducing the particle-free conductive ink to provide a metallic conductive film.

Aspect 34. The method according to any preceding method aspect, wherein the reducing step comprises one or more of: exposing the substrate to an elevated temperature; exposing the substrate to a reactive gas; and exposing the substrate to irradiation.

Aspect 35. The method according to any preceding method aspect, wherein the electron accepting material is coated over the electron donating material either before or after reducing the particle-free conductive ink to provide the metallic conductive film.

Aspect 36. The method according to any preceding method aspect, wherein the particle-free conductive ink comprises a metal complex dissolved in one or more polar protic solvents, wherein the metal complex comprises a metal, a first ligand that is a sigma donor to the metal and volatilizes upon heating the metal complex, and a second ligand, which is different from the first ligand and also volatilizes upon heating the metal complex.

Aspect 37. The method according to any preceding method aspect, wherein the metal is copper, silver, gold, or nickel.

Aspect 38. The method according to any preceding method aspect, wherein the first ligand of the metal complex is an amine or a thioether, and the second ligand of the metal complex is a carboxylate.

Aspect 39. The method according to any preceding method aspect, wherein the first, second, and/or third flexible layers are textile layers, and the particle-free conductive ink conformally coats fibers of the textile layers.

Aspect 41. The method according to any preceding method aspect, further comprising thermoforming or embossing the second flexible layer to form a raised pattern thereon, wherein a depth of the raised pattern defines the gap distance.

Aspect 42. The method according to any preceding method aspect, wherein the particle-free conductive ink comprises from 0.1% to 5% of an additive selected from one or more of a binder, a surfactant, a dispersant, and a dye.

Aspect 43. The method according to any preceding method aspect, wherein the particle-free conductive ink has a viscosity measured at 25° C. of 25 cps or less, such as 20 cps or less.

Aspect 44. The method according to any preceding method aspect, wherein the textile comprises a knit, woven, or nonwoven fabric comprising fibers of polyester, polyamides, spandex, nylon, Evolon®, elastane, cotton, cellulose, silk, wood, wool, or blends thereof.

Aspect 45. The method according to any preceding method aspect, wherein the textile substrate is pretreated with oxygen plasma, corona, a protective coating, or a combination thereof.

1. A triboelectric energy generator comprising:
a first flexible layer having a first electron donating material coated on at least a first surface and an electron accepting material coated over the first electron donating material; and
a second flexible layer having a second electron donating material coated on at least a first surface, wherein the second electron donating material comprises a conductive metal film deposited by a particle-free metal ink,
wherein the first and second layers are positioned adjacent each other with their first surfaces facing inward toward each other and separated by a gap distance, and
wherein an electric potential is generated upon movement between the first and second flexible layers, wherein the movement is at least alternating contact and no-contact between the first and second flexible layers.

2. The triboelectric energy generator of claim 1, wherein the first and second flexible layers are textile layers, wherein each textile layer is independently selected from a knit, woven, or nonwoven fabric comprising fibers of polyester, polyamide, spandex, nylon, Evolon®, elastane, cotton, cellulose, silk, wood, wool, or blends thereof.

3. The triboelectric energy generator of claim 1, wherein the particle-free metal ink comprises copper, silver, gold, or nickel.

4. The triboelectric energy generator of claim 2, wherein the particle-free conductive metal ink conformally coats fibers of the textile of the second flexible layer.

5. The triboelectric energy generator of claim 1, wherein the first electron donating material comprises a conductive metal film deposited by a particle-free metal ink, and the first and second flexible layers are textile layers.

6. The triboelectric energy generator of claim 5, wherein the particle-free metal ink of the first and second electron donating materials is deposited by a particle-free silver ink that conformally coats fibers of the textile layer.

7. The triboelectric energy generator of claim 1, wherein the gap distance is about 0.01 mm to about 5 mm, such as 0.1 mm to about 2 mm.

8. The triboelectric energy generator of claim 1, wherein a work function of the electron accepting material is at least 3 eV greater than a work function of the electron donating material.

9. The triboelectric energy generator of claim 1, wherein the electron accepting material comprises a flexible polymeric material such as polydimethylsiloxane, polyimide, or silicon rubber.

10. The triboelectric energy generator of claim 1, further comprising a third flexible layer positioned within the gap between the first and second flexible layers.

11. The triboelectric energy generator of claim 10, wherein the third flexible layer comprises a mesh material having at least a 60% open area, such as at least an 80% open area.

12. The triboelectric energy generator of claim 11, wherein the mesh material comprises a flexible polymeric material, such as nylon.

13. The triboelectric energy generator of claim 1, further comprising a protective coating over either or both of the second electron donating material or the first and second electron donating materials.

14. The triboelectric energy generator of claim 1, wherein the second flexible layer comprises a raised pattern formed by thermoforming or embossing, wherein a depth of the raised pattern defines the gap distance.

15. (canceled)

16. (canceled)

17. (canceled)

18. (canceled)

19. (canceled)

20. (canceled)

21. (canceled)

22. (canceled)

23. (canceled)

24. (canceled)

25. (canceled)

26. A method for forming a triboelectric energy generator in a flexible substrate, the method comprising:
depositing a particle-free conductive ink on at least a first side of a first flexible substrate;
coating the particle-free conductive ink on the first side of the first flexible substrate with a flexible polymeric material;
depositing the particle-free conductive ink on at least a first side of a second flexible substrate; and
reducing the particle-free conductive ink to provide a metallic conductive film;
positioning the first and second flexible substrates adjacent each other with their first surfaces facing inward toward each other and separated by a gap distance,
wherein an electric potential is generated upon movement between the first and second flexible layers.

27. (canceled)

28. The method of claim 26, wherein the reducing step comprises one or more of: exposing the substrate to an elevated temperature; exposing the substrate to a reactive gas; and exposing the substrate to irradiation.

29. The method of claim 26, further comprising: after reducing the particle-free conductive ink to provide the metallic conductive film, coating at least the metallic conductive film on the second flexible substrate with a protective coating.

30. The method of claim 26, wherein the particle-free conductive ink comprises a metal complex dissolved in one or more polar protic solvents, wherein the metal complex comprises a metal, a first ligand that is a sigma donor to the metal and volatilizes upon heating the metal complex, and a second ligand, which is different from the first ligand and also volatilizes upon heating the metal complex, and wherein the metal is copper, silver, gold, or nickel.

31. (canceled)

32. (canceled)

33. The method of claim 26, wherein the first and second flexible layers are textile layers, and the particle-free conductive ink conformally coats fibers of the textile of the second flexible layer.

34. (canceled)

35. The method of claim 26, further comprising: thermoforming or embossing the second flexible layer to form a raised pattern thereon, wherein a depth of the raised pattern defines the gap distance.

36. (canceled)

37. (canceled)

38. (canceled)

39. (canceled)
